(19) United States
(12) Patent Application Publication
(10) Pub. No.: US 2024/0132730 A1
(43) Pub. Date: Apr. 25, 2024

(54) LIQUID-REPELLING AGENT, CURABLE COMPOSITION, CURED PRODUCT, DIVIDING WALL, ORGANIC ELECTROLUMINESCENT ELEMENT, METHOD FOR PRODUCING FLUORINE-CONTAINING COATING FILM, AND FLUORINE-CONTAINING COATING FILM

(71) Applicant: CENTRAL GLASS COMPANY, LIMITED, Yamaguchi (JP)

(72) Inventors: Yuta SAKAIDA, Saitama (JP); Keita HATTORI, Saitama (JP); Yuki FURUYA, Saitama (JP); Yuzuru KANEKO, Saitama (JP)

(73) Assignee: CENTRAL GLASS COMPANY, LIMITED, Yamaguchi (JP)

(21) Appl. No.: 18/275,887

(22) PCT Filed: Feb. 1, 2022
(86) PCT No.: PCT/JP2022/003827

§ 371 Date: Aug. 4, 2023

(30) Foreign Application Priority Data
Feb. 8, 2021 (JP) 2021-018545

(51) Int. Cl. C09D 5/16; C08F 8/30; C08F 220/22; C08F 220/28; C08F 290/12; C09D 133/16; G03F 7/038; H10K 50/84

(52) U.S. Cl. CPC C09D 5/16; C08F 8/30; C08F 220/22; C08F 220/281; C08F 290/126; C09D 133/16; G03F 7/038; H10K 50/84

(57) ABSTRACT

Provided is a liquid-repellent agent which enables the production of partition walls that are less susceptible to reduction in liquid repellency even when subjected to oxygen plasma treatment or UV-ozone treatment. A liquid-repellent agent (A) of the present invention contains a polymer containing: a polymerization unit (a1) derived from a hydrocarbon having an alkyl group in which at least one hydrogen atom is replaced with a fluorine atom and which may contain an ether-oxygen atom; and one or two or more types of polymerization units (a2) other than the polymerization unit (a1), wherein the number of ethylenically unsaturated double bonds in the polymerization units (a1) and (a2) is 3 or greater.

### TECHNICAL FIELD

The present disclosure relates to a liquid-repellent agent, a curable composition, a cured product, a partition wall, an organic electroluminescent element, a method of producing a fluorine-containing coating film, and a fluorine-containing coating film.

### BACKGROUND ART

The inkjet method is known as a technique for forming an organic layer having a light emitting function or the like in the production of a display element such as an organic EL display, a micro-LED display, or a quantum dot display. There are several inkjet methods. Specific methods include one in which ink is dropped from a nozzle into the recesses of a patterned film having recesses and projections formed on a substrate and the ink is then solidified; and one in which a patterned film is formed on a substrate in advance to provide a lyophilic portion that gets wet with ink and a liquid-repellant portion that repels ink, and ink droplets are dropped onto the patterned film, whereby the ink is attached only to the lyophilic portion.

Particularly, in the former method, in which ink dropped from a nozzle into the recesses of a patterned film is solidified, mainly two processes are applicable to produce such a patterned film having recesses and projections. One is a photolithography process in which the surface of a photosensitive resist film applied to a substrate is exposed to light in a pattern form to form exposed and unexposed portions, and either of the portions is dissolved in a developer and removed; and the other is an imprinting process that uses printing technology. In general, after a patterned film having recesses and projections is formed, the entire substrate surface is subjected to UV-ozone treatment or oxygen plasma treatment. With the UV-ozone treatment or oxygen plasma treatment, particularly the organic matter remaining in the recesses of the patterned film can be removed, so that uneven wetting with the dropped ink can be reduced to prevent failure of the display element.

The projections of the patterned film having recesses and projections formed are called banks (partition walls). The banks serve as barriers against mixing of ink droplets when ink is dropped into the recesses of the patterned film. To enhance the effect of the barriers, the substrate surface is required to be exposed at the recesses of the patterned film and to be lyophilic to ink, and the upper bank surface is required to have liquid repellency with respect to ink.

Such partition walls may be formed with fluororesins. The use of fluororesins improves the liquid repellency of the formed partition walls.

Patent Literature 1 discloses a fluororesin-containing resist composition which contains a fluororesin (A) that contains a monomer unit derived from a monomer represented by Formula 1 and has a fluorine atom content of 7 to 35 mass %, and a photosensitive component reactive with light having a wavelength of 100 to 600 nm, wherein the percentage of the fluororesin (A) relative to the total solids of the resist composition is 0.1 to 30 mass %, and the photosensitive component contains a photoacid generator (B), an alkali-soluble resin (C) containing a carboxy group and/or a phenolic hydroxy group, and an acid crosslinking agent (D) which is a compound having two or more groups that are reactive with a carboxy group or a phenolic hydroxy group by the action of acid.

CH₂═C(R¹)COOXR^{f} Formula 1

In Formula 1, R¹ represents a hydrogen atom, a methyl group, or a trifluoromethyl group, X represents a C1-C6 divalent organic group containing no fluorine atom, and R^{f} represents a C4-C6 perfluoroalkyl group.

Patent Literature 2 discloses an ink-repellent agent containing a fluorine atom-containing polymerization unit, wherein the ink-repellent agent includes a polymer containing a polymerization unit (b1) having an alkyl group of C20 or less in which at least one hydrogen atom is replaced with a fluorine atom, provided that the alkyl group includes one having an ether-oxygen atom, and a polymerization unit (b2) having an ethylenic double bond, and the ink-repellent agent has a fluorine content of 5 to 25 mass % and a number average molecular weight of at least 500 but less than 10,000.

Patent Literature 3 discloses a fluororesin-containing resist composition which contains a fluororesin (A) that contains a monomer unit derived from a monomer represented by Formula 1, has an ethylenic double bond, and has a fluorine atom content of 7 to 35 mass %, and a photosensitive component reactive with light having a wavelength of 100 to 600 nm, wherein the percentage of the fluororesin (A) relative to the total solids of the resist composition is 0.1 to 30 mass %, and the photosensitive component contains a photo-radical initiator (E) and an alkali-soluble resin (F) that has in one molecule an acidic group and two or more ethylenic double bonds.

CH₂═C(R¹)COOXR^{f} Formula 1

In Formula 1, R¹ represents a hydrogen atom, a methyl group, or a trifluoromethyl group, X represents a C1-C6 divalent organic group containing no fluorine atom, and R^{f} represents a C4-C6 perfluoroalkyl group.

Patent Literature 4 discloses a negative photosensitive resin composition containing a fluorine atom-containing ink-repellent agent, wherein the negative photosensitive resin composition contains a photocurable alkali-soluble resin or alkali-soluble monomer (A), a photo-radical polymerization initiator (B), a photoacid generator (C), an acid curing agent (D), and a fluorine atom-containing ink-repellent agent (E), and the ink-repellent agent (E) has a fluorine atom content of 1 to 40 mass % and contains an ethylenic double bond.

### CITATION LIST

### Patent Literature

Patent Literature 1: JP 4474991 B

Patent Literature 2: JP 4488098 B

Patent Literature 3: JP 4905563 B

Patent Literature 4: JP 6536578 B

### SUMMARY OF INVENTION

### Technical Problem

As described above, in the formation of banks (partition walls) with the resist compositions or the like disclosed in Patent Literatures 1 to 4, UV-ozone treatment or oxygen plasma treatment is performed after forming a patterned film. While this treatment can remove the organic matter remaining on the patterned film and reduce uneven wetting with the dropped ink, it may also reduce the liquid repellency of the banks (partition walls). The banks (partition walls) then undergo heat treatment, which to some extent recovers the liquid repellency of the banks (partition walls). However, even with the heat treatment, the liquid repellency of the banks (partition walls) is not sufficient.

The present disclosure aims to provide a liquid-repellent agent that enables the production of partition walls that are less susceptible to reduction in liquid repellency even when subjected to oxygen plasma treatment or UV-ozone treatment.

### Solution to problem

In view of the problems above, the present inventors made extensive studies. As a result, they have found out that partition walls formed with a liquid-repellent agent containing a polymer having a predetermined structure are less susceptible to reduction in liquid repellency even when subjected to UV-ozone treatment or oxygen plasma treatment.

Specifically, the present disclosure is as follows.

A liquid-repellent agent (A) of the present disclosure contains a polymer containing: a polymerization unit (a1) derived from a hydrocarbon having an alkyl group in which at least one hydrogen atom is replaced with a fluorine atom and which may contain an ether-oxygen atom; and one or two or more types of polymerization units (a2) other than the polymerization unit (a1), wherein the number of ethylenically unsaturated double bonds in the polymerization units (a1) and (a2) is 3 or greater.

The liquid-repellent agent (A) of the present disclosure contains a polymer containing a polymerization unit (a1) derived from a hydrocarbon having an alkyl group in which at least one hydrogen atom is replaced with a fluorine atom and which may contain an ether-oxygen atom, and a polymerization unit (a21′) containing two or more ethylenically unsaturated double bonds.

In the liquid-repellent agent (A) of the present disclosure, the polymer preferably has a fluorine atom content of 10 to 55 mass %.

In the liquid-repellent agent (A) of the present disclosure, the ethylenically unsaturated double bonds are each preferably derived from an acrylic group or a methacrylic group.

In the liquid-repellent agent (A) of the present disclosure, the polymer preferably has a structure represented by the following formula (1):

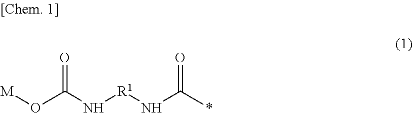

wherein M represents a structure containing two or more ethylenically unsaturated double bonds; R¹ represents a divalent organic linking group with or without a substituent; and * represents a bond.

In the liquid-repellent agent (A) of the present disclosure, the polymer preferably has a structure represented by the following formula (2):

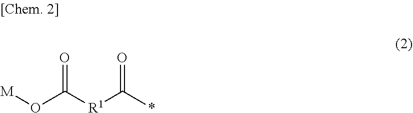

wherein M represents a structure containing two or more ethylenically unsaturated double bonds; R¹ represents a divalent organic linking group with or without a substituent; and * represents a bond.

In the liquid-repellent agent (A) of the present disclosure, the polymer preferably has a structure represented by the following formula (3):

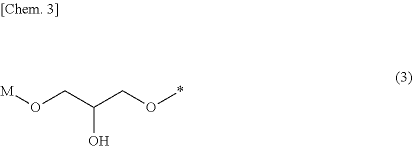

wherein M represents a structure containing two or more ethylenically unsaturated double bonds; and * represents a bond.

A curable composition of the present disclosure contains: the liquid-repellent agent (A) of the present disclosure; a resin component (B) including at least one of an alkali-soluble resin (B1) or an alkali-soluble monomer (B2); and a photopolymerization initiator (C).

The curable composition of the present disclosure preferably further contains a crosslinking agent (D).

The curable composition of the present disclosure preferably further contains a polymerization inhibitor (E).

The curable composition of the present disclosure preferably further contains an ultraviolet absorber (F).

The curable composition of the present disclosure preferably further contains a chain transfer agent (G).

The curable composition of the present disclosure is preferably for forming a partition wall.

A cured product of the present disclosure is obtained by curing the curable composition of the present disclosure.

A partition wall of the present disclosure includes the cured product of the curable composition of the present disclosure.

An organic electroluminescent element of the present disclosure includes the partition wall of the present disclosure.

A method of producing a fluorine-containing coating film of the present disclosure includes: mixing the liquid-repellent agent (A) of the present disclosure, a resin component (B) including at least one of an alkali-soluble resin (B1) or an alkali-soluble monomer (B2), and a photopolymerization initiator (C) to prepare a curable composition; applying the curable composition to a substrate, and after the applying, curing the curable composition by irradiation with high energy rays.

A fluorine-containing coating film of the present disclosure is a fluorine-containing coating film formed on a substrate, wherein a value of a contact angle of the fluorine-containing coating film with propylene glycol monomethyl ether acetate after oxygen plasma treatment for 30 minutes is 95% to 100% of a value of a contact angle of the fluorine-containing coating film with propylene glycol monomethyl ether acetate before the oxygen plasma treatment.

A fluorine-containing coating film of the present disclosure is a fluorine-containing coating film formed on a substrate, wherein a value of a contact angle of the fluorine-containing coating film with propylene glycol monomethyl ether acetate after UV-ozone treatment for 30 minutes is 95% to 100% of a value of a contact angle of the fluorine-containing coating film with propylene glycol monomethyl ether acetate before the UV-ozone treatment.

### Advantageous Effects of Invention

The use of the liquid-repellent agent of the present disclosure enables the production of partition walls that are less susceptible to reduction in liquid repellency even when subjected to oxygen plasma treatment or UV-ozone treatment.

### DESCRIPTION OF EMBODIMENTS

The present disclosure is described in detail below. The following description of structural elements provides exemplary embodiments of the present disclosure. The present disclosure is not limited to such specific contents. Various modifications can be made within the scope of the gist.

In the section “DESCRIPTION OF EMBODIMENTS” herein, the matters denoted by the brackets “[” and “]” and “<” and “>” are merely symbols and have no meaning per se.

Herein, the term “bank” or “banks” is a synonym to the term “partition wall” or “partition walls”, and these terms refer to projection(s) of a patterned film having recesses and projections used in an inkjet method, unless otherwise specified.

### First Embodiment

A liquid-repellent agent (A) according to a first embodiment of the present disclosure contains a polymer containing a polymerization unit (a1) derived from a hydrocarbon having an alkyl group in which at least one hydrogen atom is replaced with a fluorine atom and which may contain an ether-oxygen atom, and one or two or more types of polymerization units (a2) other than the polymerization unit (a1), wherein the number of ethylenically unsaturated double bonds in the polymerization units (a1) and (a2) is 3 or greater.

The use of the liquid-repellent agent (A) according to the first embodiment of the present disclosure enables the production of partition walls that are less susceptible to reduction in liquid repellency even when subjected to oxygen plasma treatment or UV-ozone treatment.

Here, the following is a predicted reason why the use of the liquid-repellent agent (A) of the present disclosure enables the production of partition walls that are less susceptible to reduction in liquid repellency even when subjected to oxygen plasma treatment or UV-ozone treatment.

When partition walls are formed with conventional liquid-repellent agents, their liquid repellency is reduced by oxygen plasma treatment or UV-ozone treatment because these treatments break the bonds of the polymer constituting the partition walls to increase the hydrophilicity of the surfaces of the partition walls.

The ethylenically unsaturated double bonds in the polymer can inhibit the breakage of the bonds of the polymer due to the oxygen plasma treatment or UV-ozone treatment.

The polymer in the liquid-repellent agent (A) according to the first embodiment of the present disclosure is constituted by polymerization units containing many ethylenically unsaturated double bonds. Thus, even when partition walls formed with the liquid-repellent agent (A) according to the first embodiment of the present disclosure are subjected to oxygen plasma treatment or UV-ozone treatment, the hydrophilicity of the surfaces of the partition walls is less likely to increase, so that the partition walls are less susceptible to reduction in liquid repellency.

Herein, the meaning of the term “polymerization unit” is as follows.

A polymer is formed by polymerization of a single or multiple monomers. The term “polymerization unit” means a type of portion derived from a monomer constituting a polymer.

Moreover, the term “ethylenically unsaturated double bond in a polymerization unit” means an ethylenically unsaturated double bond located in a side chain of a polymer, and does not encompass an ethylenically unsaturated double bond of a monomer that contributes to a polymerization reaction.

In the liquid-repellent agent (A) according to the first embodiment of the present disclosure, the percentage of ethylenically unsaturated double bonds in the polymer is preferably 0.1 to 10 mass %, more preferably 0.5 to 3 mass % relative to the mass of the total polymer.

When the percentage is not lower than the lower limit value, the resistance to oxygen plasma treatment and UV-ozone treatment tends to improve. When the percentage is not higher than the upper limit value, a desired pattern tends to be easily formed.

In the liquid-repellent agent (A) according to the first embodiment of the present disclosure, the number of ethylenically unsaturated double bonds in the polymerization units (a1) and (a2) is 3 or greater.

The number of ethylenically unsaturated double bonds in the polymerization units (a1) and (a2) means the total number of ethylenically unsaturated double bonds in the chemical structures measured for the chemical structures of each polymerization unit (a1) and each polymerization unit (a2) constituting the polymer.

Examples of such combinations of the polymerization units (a1) and (a2) include the following.
Combination 1: The polymerization unit (a1) contains no ethylenically unsaturated double bond, and the polymerization unit(s) (a2) contain three or four or more ethylenically unsaturated double bonds.
Combination 2: The polymerization unit (a1) contains one ethylenically unsaturated double bond, and the polymerization unit(s) (a2) contain two or three or more ethylenically unsaturated double bonds.
Combination 3: The polymerization unit (a1) contains two ethylenically unsaturated double bonds, and the polymerization unit(s) (a2) contain one or two or more ethylenically unsaturated double bonds.
Combination 4: The polymerization unit (a1) contains three or more ethylenically unsaturated double bonds, and the polymerization unit(s) (a2) contain no ethylenically unsaturated double bond or one or more ethylenically unsaturated double bonds.

For the liquid-repellent agent (A) according to the first embodiment of the present disclosure, the meaning of “the number of ethylenically unsaturated double bonds in the polymerization unit(s) (a2)” is as follows.

When one type of polymerization unit (a2) is present, “the number of ethylenically unsaturated double bonds in the polymerization unit(s) (a2)” is the number of ethylenically unsaturated double bonds in the one type of polymerization unit (a2).

When two or more types of polymerization units (a2) are present, and only one type of polymerization unit (a2) contains an ethylenically unsaturated double bond, “the number of ethylenically unsaturated double bonds in the polymerization unit(s) (a2)” is the number of ethylenically unsaturated double bonds in the one type of polymerization unit (a2).

When two or more types of polymerization units (a2) are present, and the two or more types of polymerization units (a2) each contain an ethylenically unsaturated double bond, “the number of ethylenically unsaturated double bonds in the polymerization unit(s) (a2)” is the total number of ethylenically unsaturated double bonds in the types of polymerization units (a2).

In the liquid-repellent agent (A) according to the first embodiment of the present disclosure, the number of ethylenically unsaturated double bonds in the polymerization units (a1) and (a2) is preferably 3 or greater, more preferably 5 or greater, still more preferably 6 or greater.

Also, in the liquid-repellent agent (A) according to the first embodiment of the present disclosure, the number of ethylenically unsaturated double bonds in the polymerization units (a1) and (a2) is preferably 10 or less.

In the liquid-repellent agent (A) according to the first embodiment of the present disclosure, the ethylenically unsaturated double bonds are each preferably derived from an acrylic group or a methacrylic group, more preferably an acrylic group.

The following describes the structural elements of the liquid-repellent agent (A) according to the first embodiment of the present disclosure.

### Polymerization Unit (a1)

The polymerization unit (a1) in the liquid-repellent agent (A) according to the first embodiment of the present disclosure may have any chemical structure as long as it is derived from a hydrocarbon having an alkyl group in which at least one hydrogen atom is replaced with a fluorine atom and which may contain an ether-oxygen atom.

The polymerization unit (a1) in the liquid-repellent agent (A) may be one or two or more types of polymerization units.

As the polymerization unit (a1) contains a fluorine atom, the partition walls formed with the liquid-repellent agent (A) of the present disclosure, which contains a polymer containing the polymerization unit (a1), have improved liquid repellency.

The polymerization unit (a1) may be a polymerization unit (a11) represented by the following formula (4).

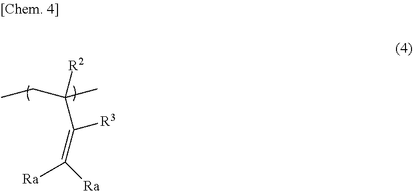

wherein each Ra independently represents a C1-C6 linear, C3-C6 branched, or C3-C6 cyclic alkyl group in which any number of hydrogen atoms are replaced with fluorine atoms, or a fluorine atom; R² represents a hydrogen atom, a fluorine atom, or a methyl group; and R³ represents a hydrogen atom, a C1-C6 linear, C3-C6 branched, or C3-C6 cyclic alkyl group.

In formula (4), R² is preferably a hydrogen atom or a methyl group, and examples of R³ include a hydrogen atom, a methyl group, an ethyl group, an n-propyl group, an isopropyl group, an n-butyl group, a 1-methylpropyl group, a 2-methylpropyl group, a tert-butyl group, an n-pentyl group, an isopentyl group, a 1,1-dimethylpropyl group, a 1-methylbutyl group, a 1,1-dimethylbutyl group, an n-hexyl group, a cyclopentyl group, and a cyclohexyl group, with a hydrogen atom, a methyl group, an ethyl group, an n-propyl group, and an isopropyl group being preferred, with a hydrogen atom or a methyl group being more preferred.

Moreover, Ra in formula (4) is preferably a fluorine atom, a trifluoromethyl group, a difluoromethyl group, a pentafluoroethyl group, a 2,2,2-trifluoroethyl group, an n-heptafluoropropyl group, a 2,2,3,3,3-pentafluoropropyl group, a 3,3,3-trifluoropropyl group, a hexafluoroisopropyl group, a heptafluoroisopropyl group, an n-nonafluorobutyl group, an isononafluorobutyl group, or a tert-nonafluorobutyl group; more preferably a fluorine atom, a trifluoromethyl group, a difluoromethyl group, a pentafluoroethyl group, a 2,2,2-trifluoroethyl group, an n-heptafluoropropyl group, a 2,2,3,3,3-pentafluoropropyl group, a 3,3,3-trifluoropropyl group, or a hexafluoroisopropyl group; particularly preferably a fluorine atom, a difluoromethyl group, or a trifluoromethyl group.

The polymerization unit (a11) contains one ethylenically unsaturated double bond.

The following are examples of preferred structures of the polymerization unit (a11).

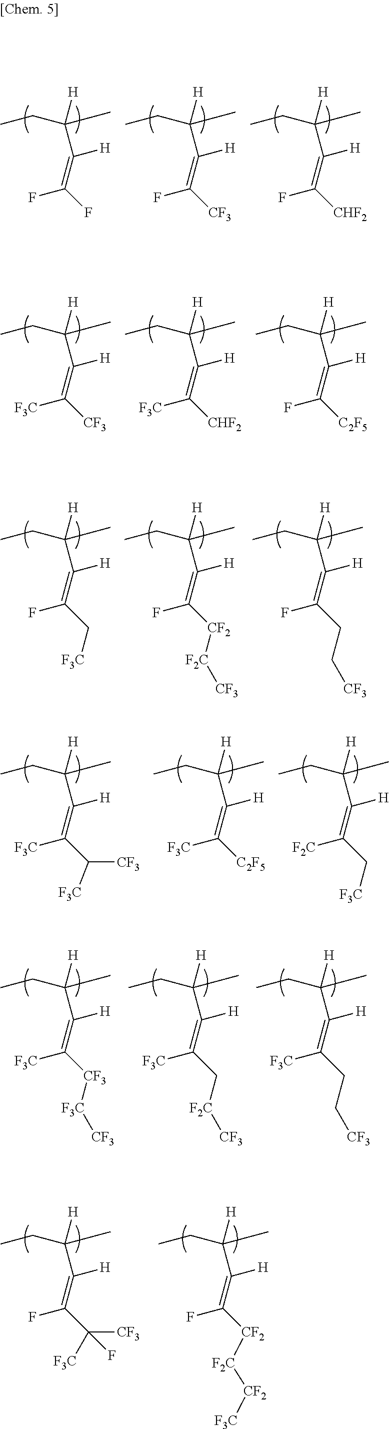

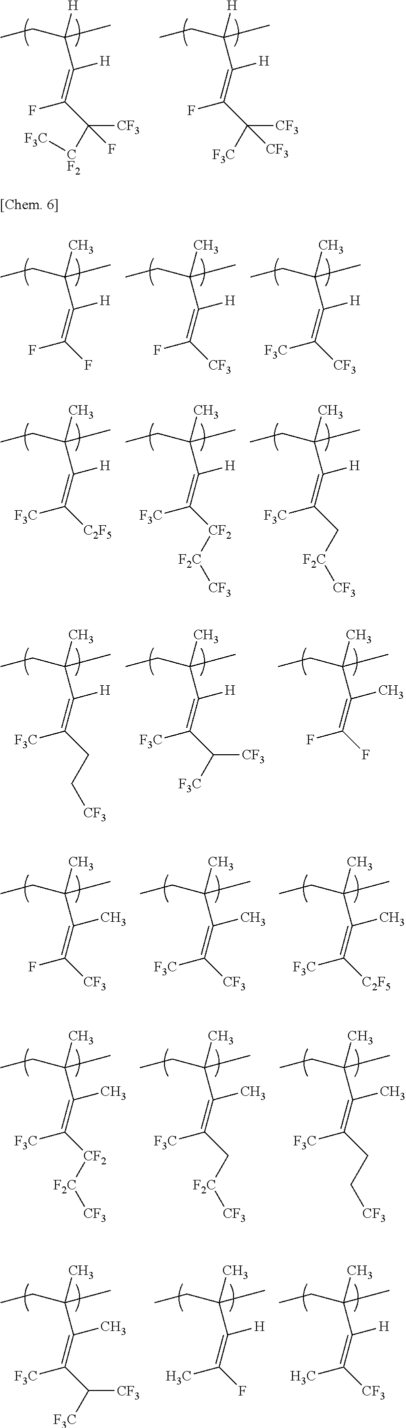

Of these, a polymerization unit represented by the following formula (5), derived from 1,1-bis(trifluoromethyl)-1,3-butadiene (BTFBE), is preferred.

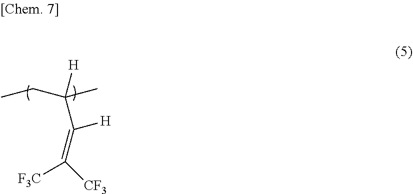

The polymerization unit (a1) may be a polymerization unit (a12) represented by the following formula (6).

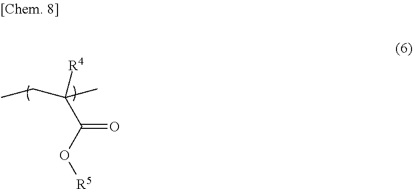

In formula (6), R⁴ represents a hydrogen atom or a methyl group.

In formula (6), R⁵ represents a C1-C15 linear, C3-C15 branched, or C3-C15 cyclic alkyl group in which at least one hydrogen atom is replaced with a fluorine atom.

When R⁵ is a linear alkyl group, specific examples thereof include a methyl group, an ethyl group, a propyl group, a butyl group, a pentyl group, a hexyl group, a heptyl group, an octyl group, a nonyl group, and C10-C14 linear alkyl groups in which at least one hydrogen atom is replaced with a fluorine atom.

The polymerization unit (a12) contains no ethylenically unsaturated double bond.

The following are examples of preferred structures of the polymerization unit (a12) of formula (6).

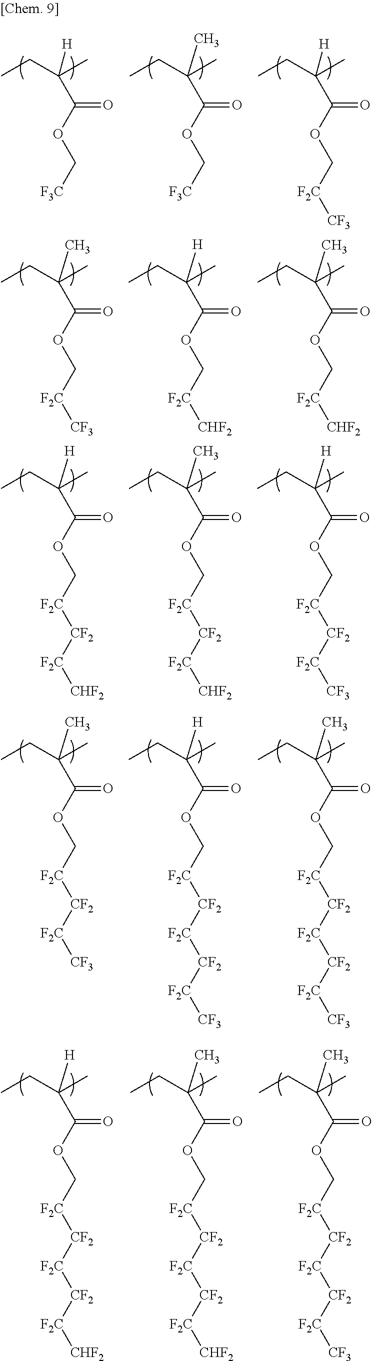

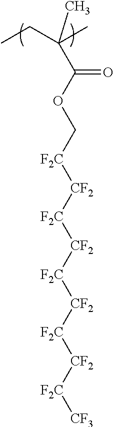

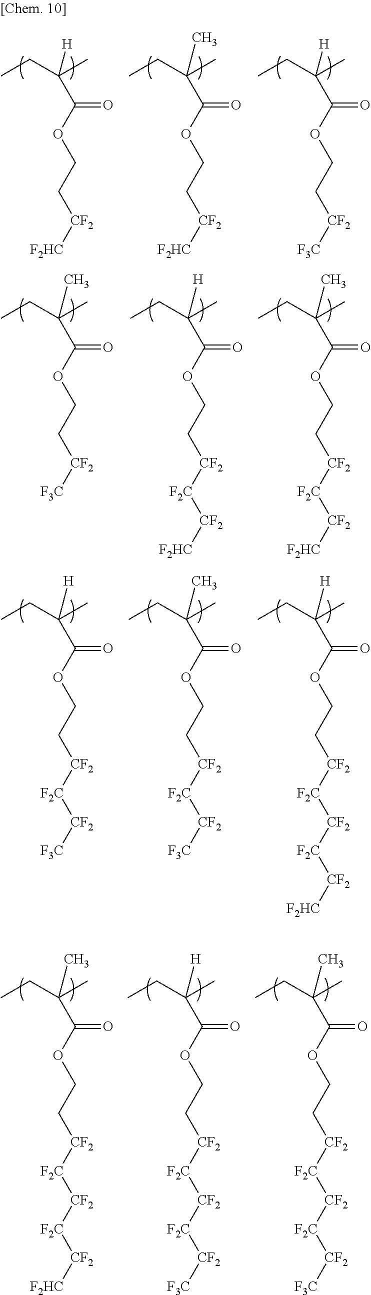

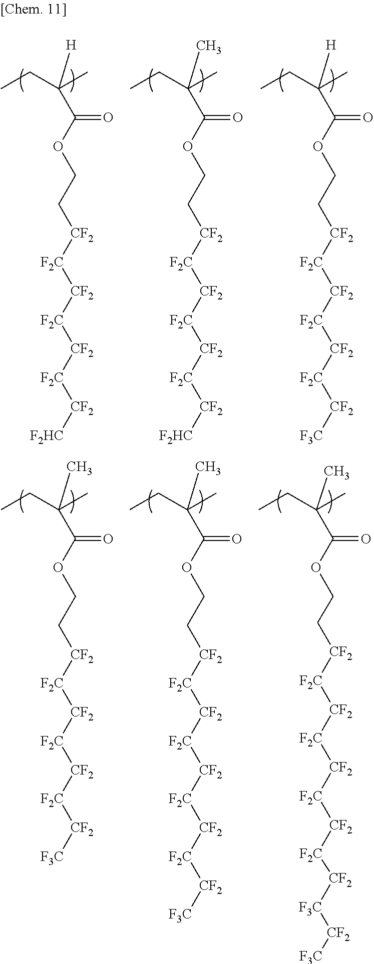

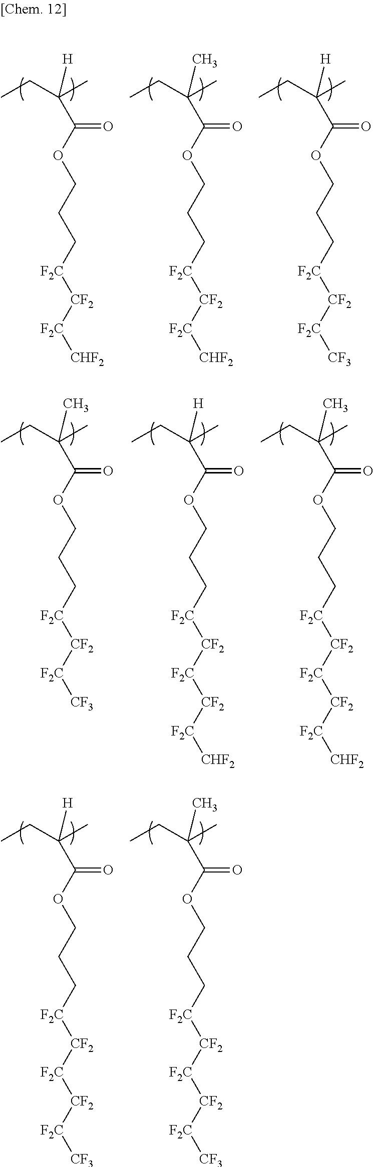

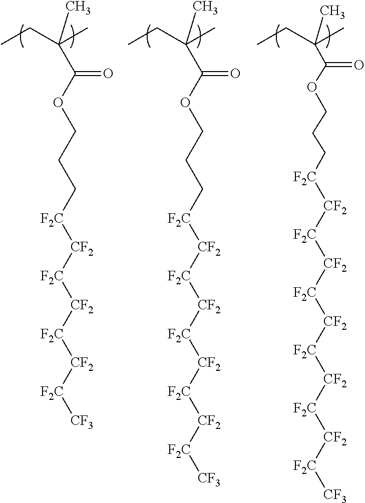

### Polymerization Unit (a2)

The polymerization unit(s) (a2) in the liquid-repellent agent (A) according to the first embodiment of the present disclosure may have any chemical structure as long as it has a structure other than that of the polymerization unit (a1).

The polymerization unit(s) (a2) is preferably a polymerization unit (a21) containing an ethylenically unsaturated double bond.

The polymerization unit (a21) containing an ethylenically unsaturated double bond may have a structure represented by the following formula (7).

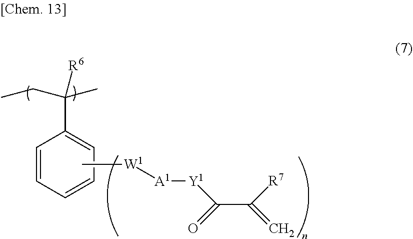

In formula (7), R⁶ and R⁷ each independently represent a hydrogen atom or a methyl group.

In formula (7), W¹ represents a divalent linking group and represents —O—, —O—C(═O)—, —C(═O)—O—, —O—C(═O)—NH—, —C(═O)—O—C(═O)—NH—, or —C(═O)—NH—. Preferred of these is —O—C(═O)—NH—, —C(═O)—O—C(═O)—NH—, or —C(═O)—NH—.

When W¹ is —O—C(═O)—NH—, the use of the liquid-repellent agent (A) according to the first embodiment of the present disclosure enables the production of partition walls that are even less susceptible to reduction in liquid repellency even when subjected to oxygen plasma treatment or UV-ozone treatment.

In formula (7), A¹ represents a divalent linking group and represents a C1-C10 linear, C3-C10 branched, or C3-C10 cyclic alkylene group in which any number of hydrogen atoms may be replaced with hydroxy groups or —O—C(═O)—CH₃.

When the divalent linking group A¹ is a C1-C10 linear alkylene group, examples thereof include a methylene group, an ethylene group, a propylene group, an n-butylene group, an n-pentylene group, an n-hexalene group, an n-heptalene group, an n-octalene group, an n-nonalene group, and an n-decalene group.

When the divalent linking group A¹ is a C3-C10 branched alkylene group, examples thereof include an isopropylene group, an isobutylene group, a sec-butylene group, a tert-butylene group, an isopentalene group, and an isohexalene group.

When the divalent linking group A¹ is a C3-C10 cyclic alkylene group, examples thereof include disubstituted cyclopropanes, disubstituted cyclobutanes, disubstituted cyclopentanes, disubstituted cyclohexanes, disubstituted cycloheptanes, disubstituted cyclooctanes, disubstituted cyclodecanes, and disubstituted 4-tert-butylcyclohexanes.

When any number of hydrogen atoms in these alkylene groups are replaced with hydroxy groups, examples of such hydroxy group-substituted alkylene groups include a hydroxyethylene group, a 1-hydroxy-n-propylene group, a 2-hydroxy-n-propylene group, a hydroxy-isopropylene group (—CH(CH₂OH)CH₂—), a 1-hydroxy-n-butylene group, a 2-hydroxy-n-butylene group, a hydroxy-sec-butylene group (—CH(CH₂OH)CH₂CH₂—), a hydroxy-isobutylene group (—CH₂CH(CH₂OH)CH₂—), and a hydroxy-tert-butylene group (—C(CH₂OH)(CH₃)CH₂—).

Also, when any number of hydrogen atoms in these alkylene groups are replaced with —O—C(═O)—CH₃, examples of such substituted alkylene groups include those in which the hydroxy groups of the hydroxy group-substituted alkylene groups exemplified above are replaced with —O—C(═O)—CH₃.

Of these, the divalent linking group A¹ is preferably a methylene group, an ethylene group, a propylene group, an n-butylene group, an isobutylene group, a sec-butylene group, a cyclohexyl group, a 2-hydroxy-n-propylene group, a hydroxy-isopropylene group (—CH(CH₂OH)CH₂—), a 2-hydroxy-n-butylene group, or a hydroxy-sec-butylene group (—CH(CH₂OH)CH₂CH₂—); more preferably an ethylene group, a propylene group, a 2-hydroxy-n-propylene group, or a hydroxy-isopropylene group (—CH(CH₂OH)CH₂—); particularly preferably an ethylene group or a 2-hydroxy-n-propylene group.

In formula (7), Y¹ represents a divalent linking group and represents —O— or —NH—, with —O— being more preferred.

In formula (7), n represents an integer of 1 to 3, with n of 1 being particularly preferred.

The substituents are each independently in the ortho, meta, or para position of the aromatic ring, with the para position being preferred.

The following structures are preferred examples of the polymerization unit of formula (7). In the examples, the substituent position on the aromatic ring is the para position, but the substituents may be each independently in the ortho or meta position.

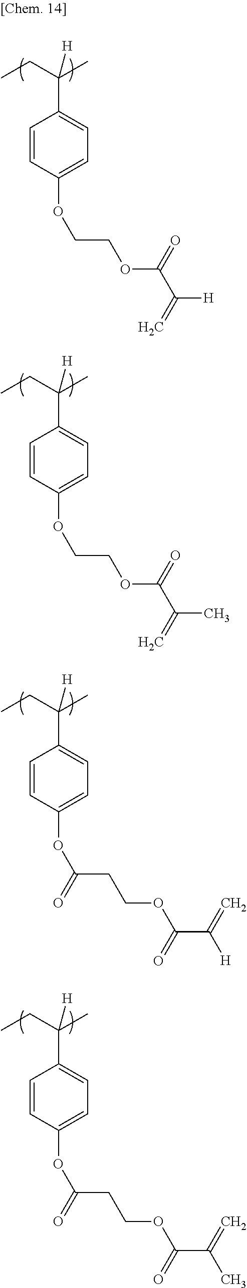

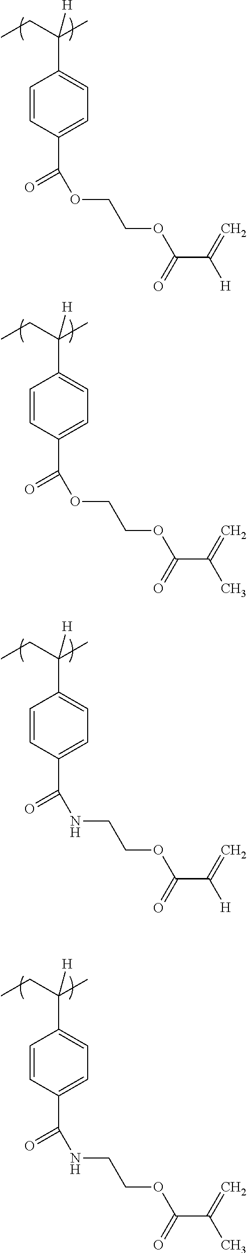

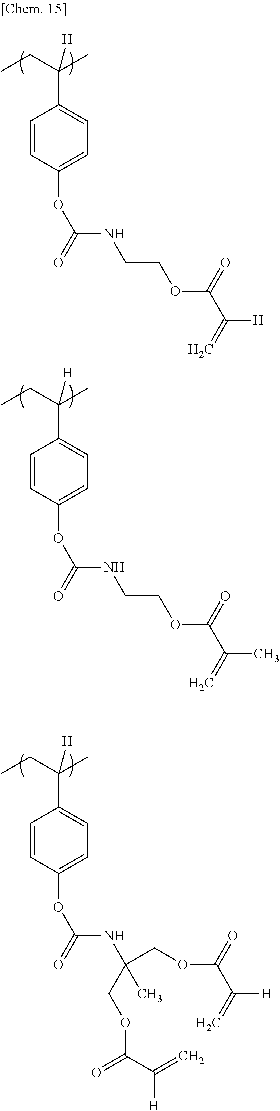

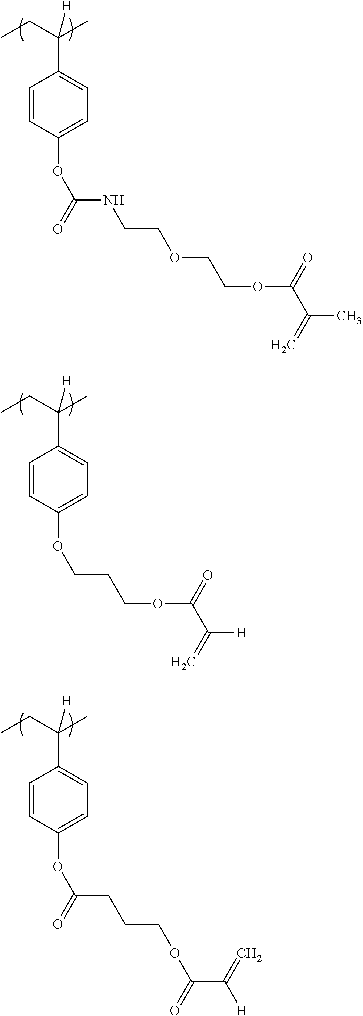

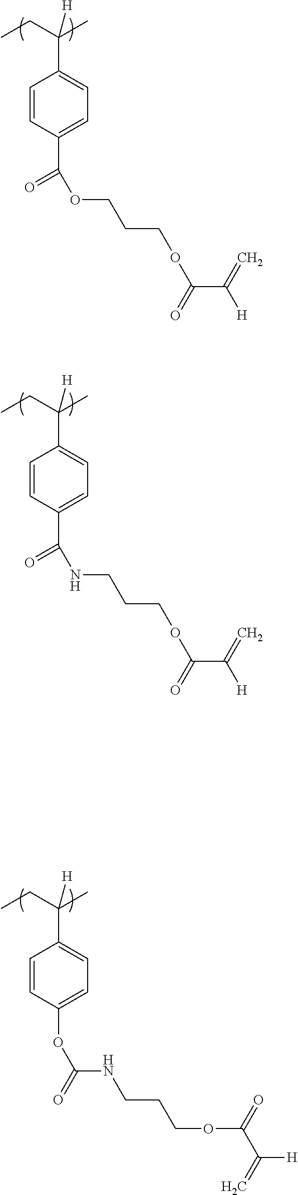

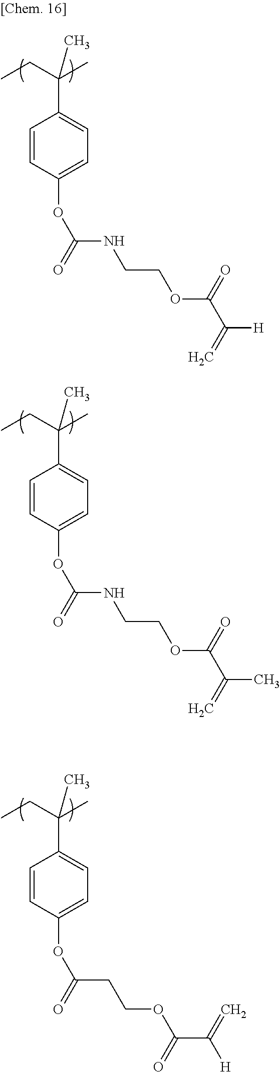

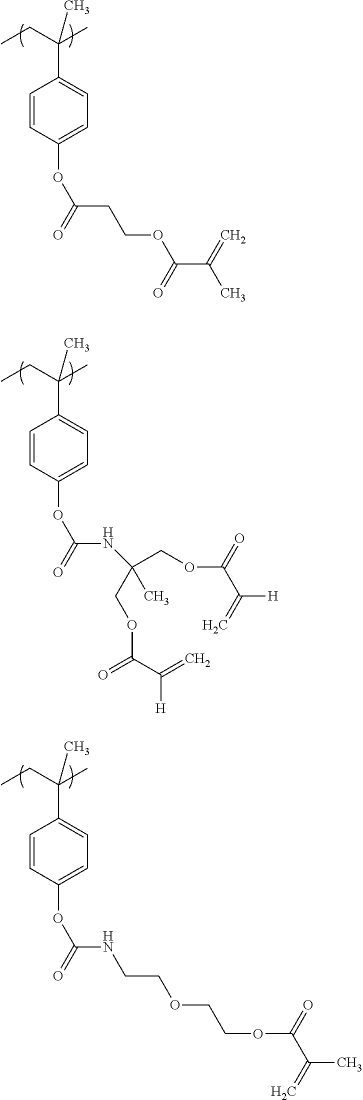

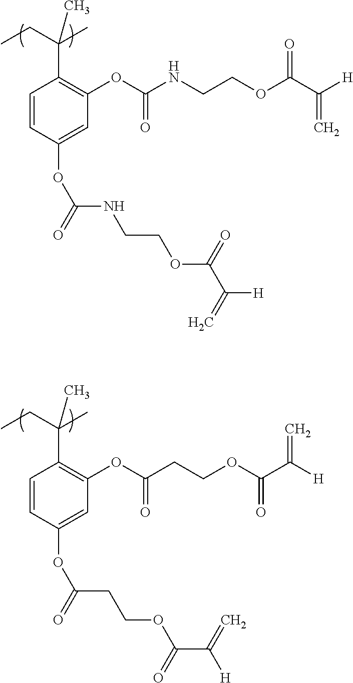

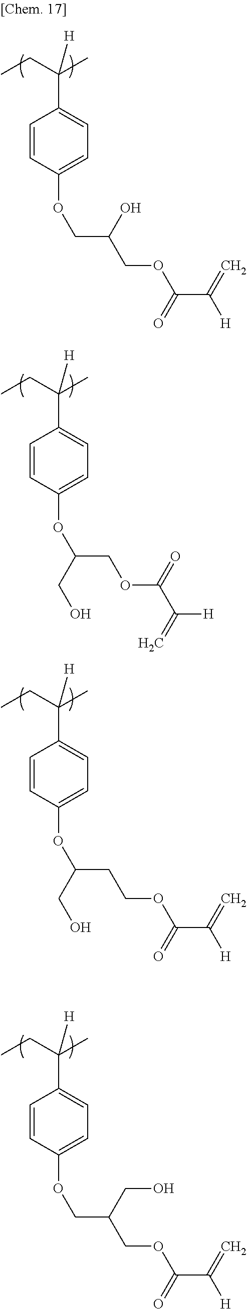

The polymerization unit (a21) containing an ethylenically unsaturated double bond may have a structure represented by the following formula (8).

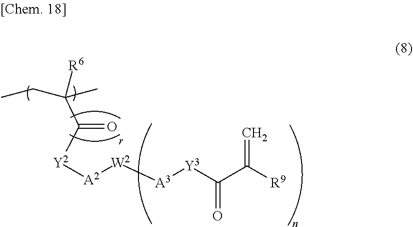

In formula (8), R⁸ and R⁹ each independently represent a hydrogen atom or a methyl group.

In formula (8), W² represents a divalent linking group and represents —O—, —O—C(═O)—, —C(═O)—O—, —O—C(═O)—NH—, —C(═O)—O—C(═O)—NH—, or —C(═O)—NH—. Preferred of these is —O—C(═O)—NH—, —C(═O)—O—C(═O)—NH—, or —C(═O)—NH—.

When W² is —O—C(═O)—NH—, the use of the liquid-repellent agent (A) according to the first embodiment of the present disclosure enables the production of partition walls that are even less susceptible to reduction in liquid repellency even when subjected to oxygen plasma treatment or UV-ozone treatment.

In formula (8), A² and A³ each independently represent a divalent linking group and represent a C1-C10 linear, C3-C10 branched, or C3-C10 cyclic alkylene group in which any number of hydrogen atoms may be replaced with hydroxy groups or —O—C(═O)—CH₃.

When the divalent linking groups A² and A³ are each independently a C1-C10 linear alkylene group, examples thereof include a methylene group, an ethylene group, a propylene group, an n-butylene group, an n-pentylene group, an n-hexalene group, an n-heptalene group, an n-octalene group, an n-nonalene group, and an n-decalene group.

When the divalent linking groups A² and A³ are each independently a C3-C10 branched alkylene group, examples thereof include an isopropylene group, an isobutylene group, a sec-butylene group, a tert-butylene group, an isopentalene group, and an isohexalene group.

When the divalent linking groups A² and A³ are each independently a C3-C10 cyclic alkylene group, examples thereof include disubstituted cyclopropanes, disubstituted cyclobutanes, disubstituted cyclopentanes, disubstituted cyclohexanes, disubstituted cycloheptanes, disubstituted cyclooctanes, disubstituted cyclodecanes, and disubstituted 4-tert-butylcyclohexanes.

When any number of hydrogen atoms in these alkylene groups are replaced with hydroxy groups, examples of such hydroxy group-substituted alkylene groups include a 1-hydroxyethylene group (—CH(OH)CH₂—), a 2-hydroxyethylene group (—CH₂CH(OH)—), a 1-hydroxy-n-propylene group, a 2-hydroxy-n-propylene group, a hydroxy-isopropylene group (—CH(CH₂OH)CH₂—), a 1-hydroxy-n-butylene group, a 2-hydroxy-n-butylene group, a hydroxy-sec-butylene group (—CH(CH₂OH)CH₂CH₂—), a hydroxy-isobutylene group (—CH₂CH(CH₂OH)CH₂—), and a hydroxy-tert-butylene group (—C(CH₂OH)(CH₃)CH₂—).

Also, when any number of hydrogen atoms in these alkylene groups are replaced with —O—C(═O)—CH₃, examples of such substituted alkylene groups include those in which the hydroxy groups of the hydroxy group-substituted alkylene groups exemplified above are replaced with —O—C(═O)—CH₃.

Of these, the divalent linking groups A² and A³ are each independently preferably a methylene group, an ethylene group, a propylene group, an n-butylene group, an isobutylene group, a sec-butylene group, a cyclohexyl group, a 1-hydroxyethylene group (—CH(OH)CH₂—), a 2-hydroxyethylene group (—CH₂CH(OH)—), a 2-hydroxy-n-propylene group, a hydroxy-isopropylene group (—CH(CH₂OH)CH₂—), a 2-hydroxy-n-butylene group, or a hydroxy-sec-butylene group (—CH(CH₂OH)CH₂CH₂—); more preferably an ethylene group, a propylene group, a 1-hydroxyethylene group (—CH(OH)CH₂—), a 2-hydroxyethylene group (—CH2CH(OH)—), a 2-hydroxy-n-propylene group, or a hydroxy-isopropylene group (—CH(CH₂OH)CH₂—); particularly preferably an ethylene group, a 1-hydroxyethylene group (—CH(OH)CH₂—), or a 2-hydroxyethylene group (—CH₂CH(OH)—).

In formula (8), Y² and Y³ represent divalent linking groups and each independently represent —O— or —NH—, with —O— being more preferred.

In formula (8), n represents an integer of 1 to 3, with n of 1 being particularly preferred.

In formula (8), r represents 0 or 1. When r is 0, (—C(═O)—) represents a single bond.

The following structures are preferred examples of the polymerization unit of formula (8).

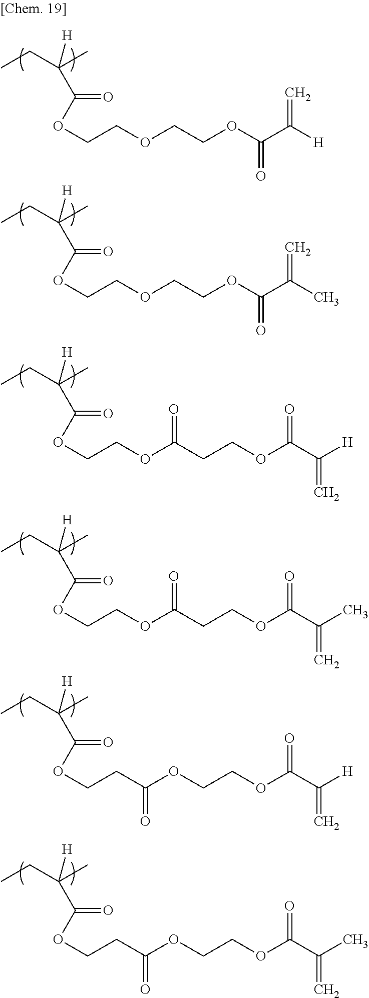

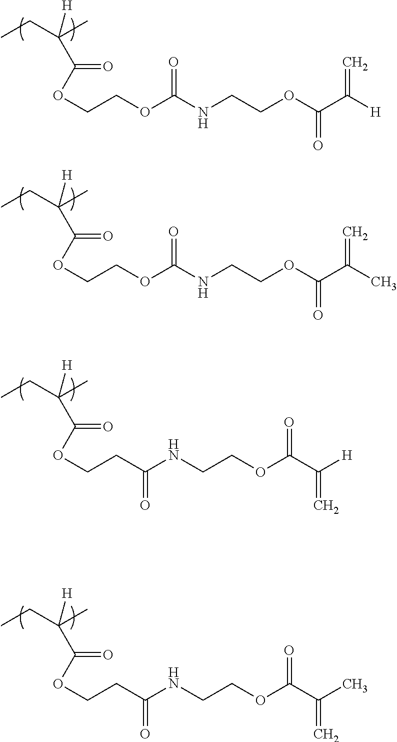

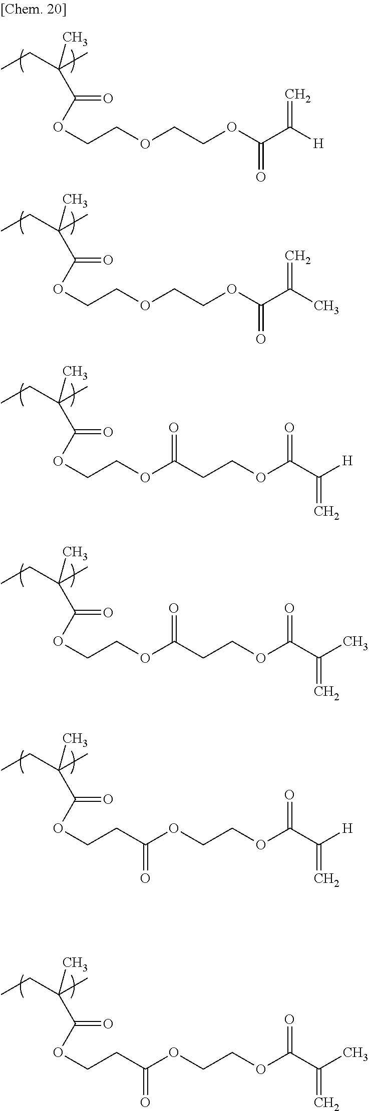

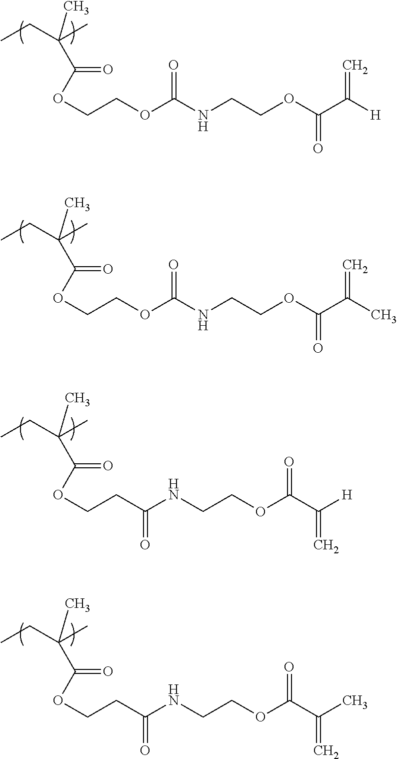

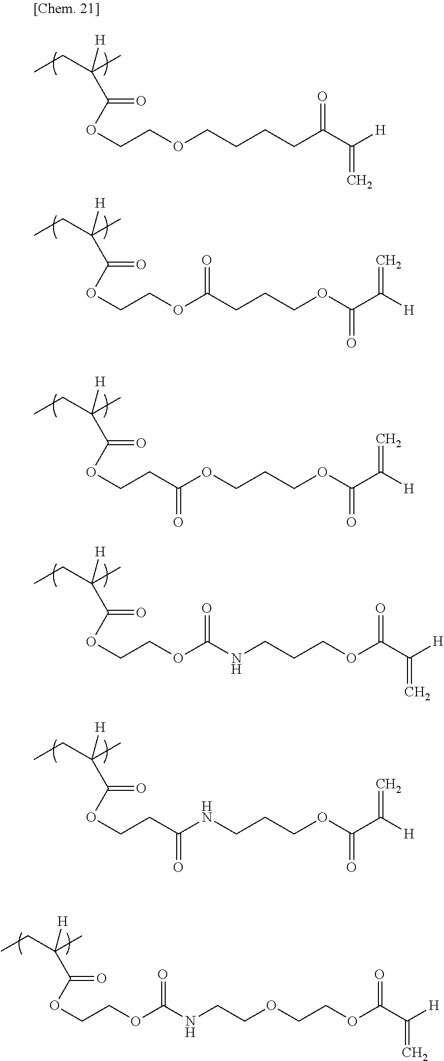

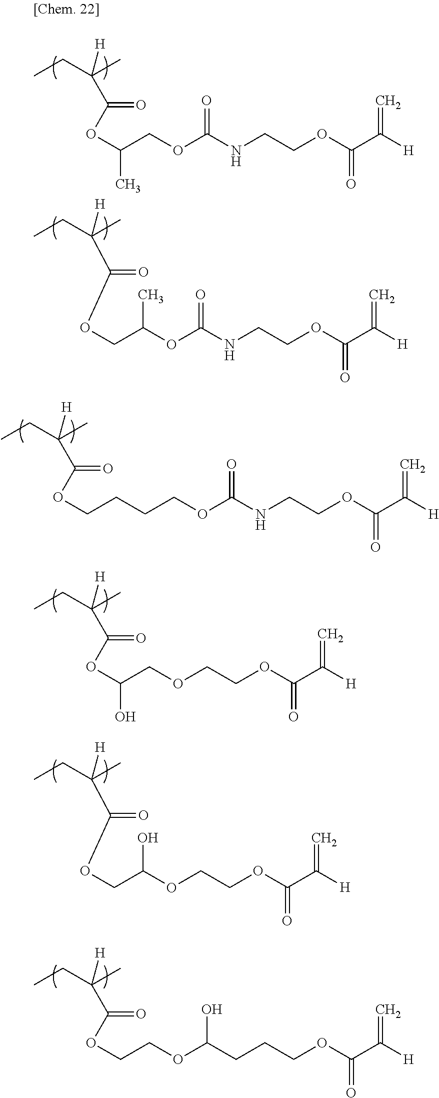

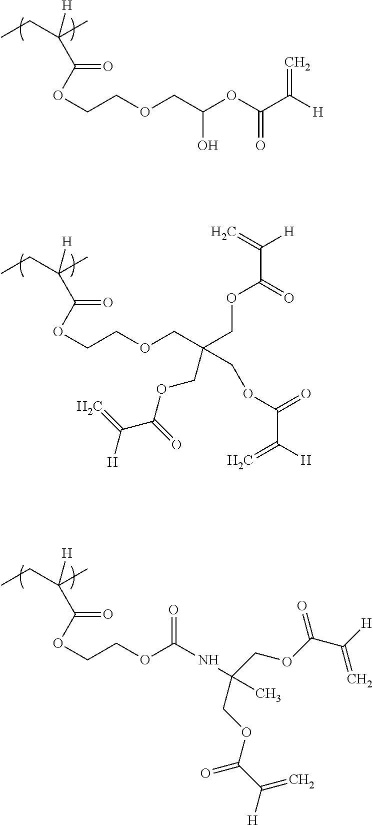

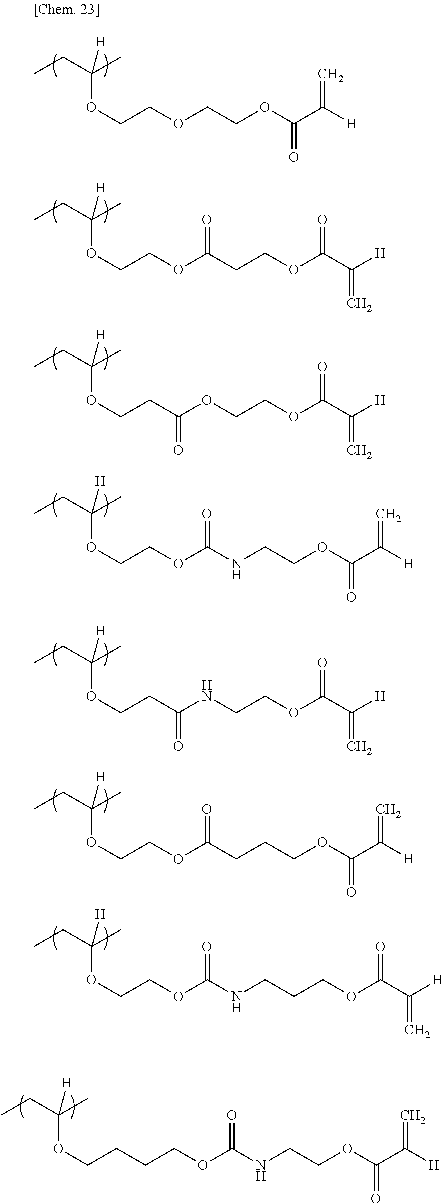

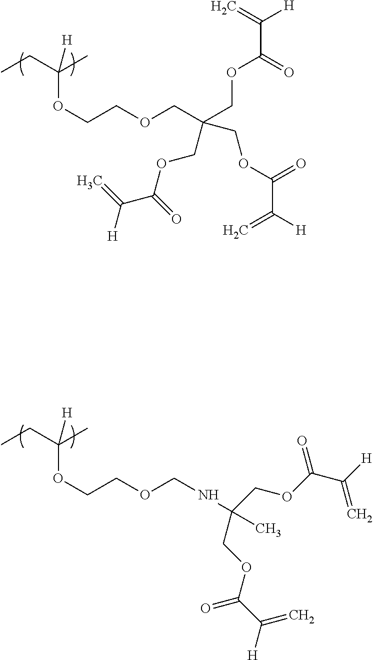

The polymerization unit (a21) containing an ethylenically unsaturated double bond is preferably a polymerization unit (a21′) containing two or more ethylenically unsaturated double bonds.

The polymerization unit (a21′) containing two or more ethylenically unsaturated double bonds preferably has a structure represented by any of the following formulas (1) to (3).

When the polymerization unit (a21′) has a structure of any of the following formulas (1) to (3), the polymer in the liquid-repellent agent (A) according to the first embodiment of the present disclosure also has the structure of any of the following formulas (1) to (3).

The use of the liquid-repellent agent (A) according to the first embodiment of the present disclosure containing such a polymer enables the production of partition walls that are even less susceptible to reduction in liquid repellency even when subjected to oxygen plasma treatment or UV-ozone treatment.

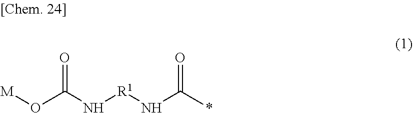

In formula (1), M represents a structure containing two or more ethylenically unsaturated double bonds; R¹ represents a divalent organic linking group with or without a substituent; and * represents a bond.

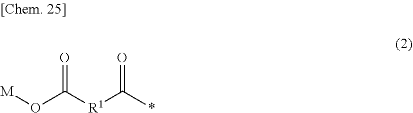

In formula (2), M represents a structure containing two or more ethylenically unsaturated double bonds; R¹ represents a divalent organic linking group with or without a substituent; and * represents a bond.

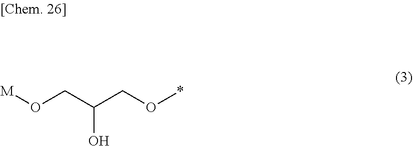

In formula (3), M represents a structure containing two or more ethylenically unsaturated double bonds; and * represents a bond.

In formulas (1) and (2), R¹ may be any divalent organic linking group with or without a substituent and may be a C1-C10 linear, C3-C10 branched, or C3-C10 cyclic alkylene group in which any number of hydrogen atoms may be replaced with hydroxy groups or —O—C(═O)—CH₃.

When R¹ is a C1-C10 linear alkylene group, examples thereof include a methylene group, an ethylene group, a propylene group, an n-butylene group, an n-pentylene group, an n-hexalene group, an n-heptalene group, an n-octalene group, an n-nonalene group, and an n-decalene group.

When R¹ is a C3-C10 branched alkylene group, examples thereof include an isopropylene group, an isobutylene group, a sec-butylene group, a tert-butylene group, an isopentalene group, and an isohexalene group.

When R¹ is a C3-C10 cyclic alkylene group, examples thereof include disubstituted cyclopropanes, disubstituted cyclobutanes, disubstituted cyclopentanes, disubstituted cyclohexanes, disubstituted cycloheptanes, disubstituted cyclooctanes, disubstituted cyclodecanes, and disubstituted 4-tert-butylcyclohexanes.

When any number of hydrogen atoms in these alkylene groups are replaced with hydroxy groups, examples of such hydroxy group-substituted alkylene groups include a 1-hydroxyethylene group (—CH(OH)CH₂—), a 2-hydroxyethylene group (—CH₂CH(OH)—), a 1-hydroxy-n-propylene group, a 2-hydroxy-n-propylene group, a hydroxy-isopropylene group (—CH(CH₂OH)CH₂—), a 1-hydroxy-n-butylene group, a 2-hydroxy-n-butylene group, a hydroxy-sec-butylene group (—CH(CH₂OH)CH₂CH₂—), a hydroxy-isobutylene group (—CH₂CH(CH₂OH)CH₂—), and a hydroxy-tert-butylene group (—C(CH₂OH)(CH₃)CH₂—).

Moreover, when the polymerization unit (a21′) has two or more other types of structures among the structures of formulas (1) to (3), R¹ or M in each structure may be the same or different.

In formulas (1) to (3), M may be any structure containing two or more ethylenically unsaturated double bonds, but is preferably a polyfunctional acrylate or methacrylate, more preferably a bi- to penta-functional acrylate, still more preferably a structure represented by the following formula (9).

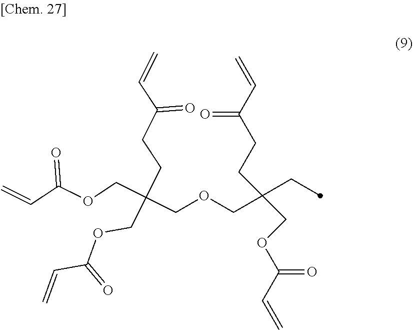

In formula (9), ⋅ represents a bond.

The following are examples of preferred structures of the polymerization unit (a21′) containing two or more ethylenically unsaturated double bonds.

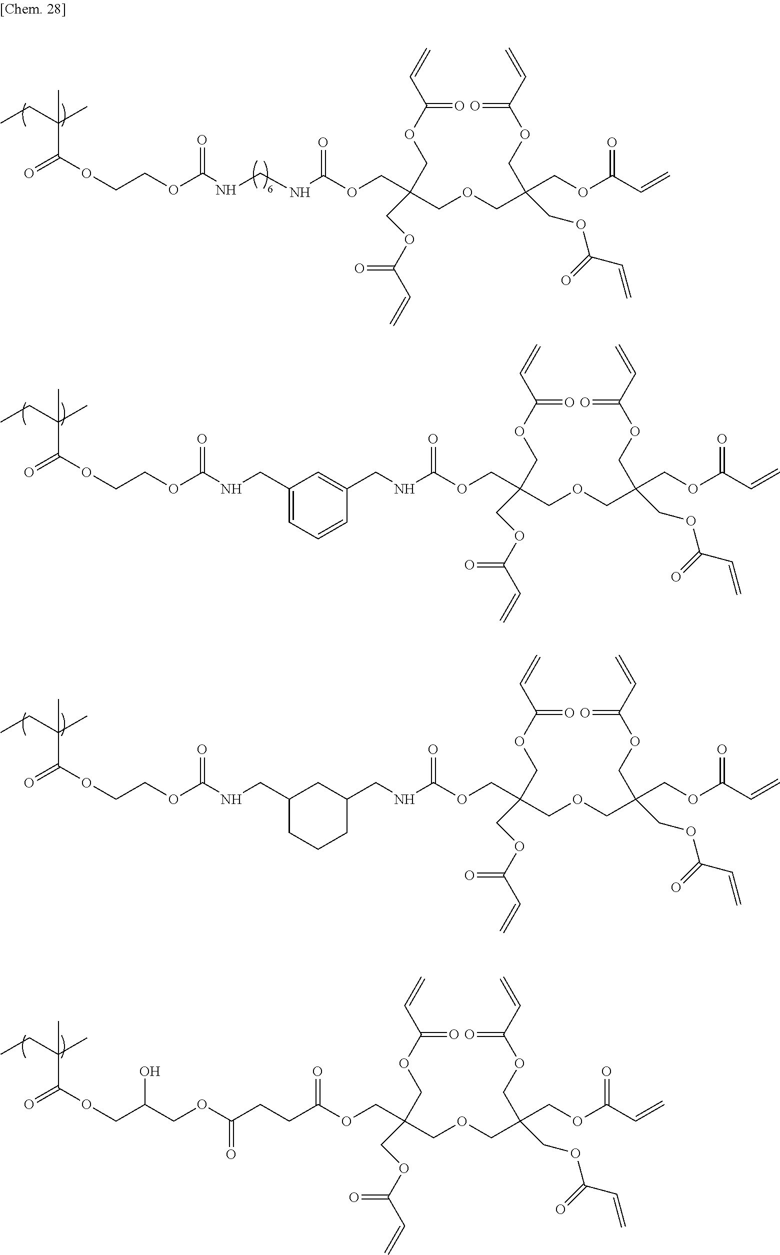

In the liquid-repellent agent (A) according to the first embodiment of the present disclosure, the polymerization unit(s) (a2) may include a polymerization unit (a22) containing no ethylenically unsaturated double bond.

The polymerization unit (a22) may have a structure represented by the following formula (10).

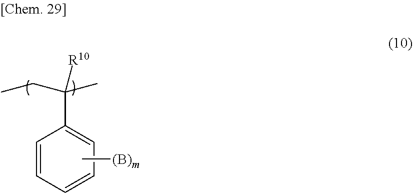

In formula (10), R¹⁰ represents a hydrogen atom or a methyl group.

In formula (10), each B independently represents a hydroxy group, a carboxy group, —C(═O)—O—R¹¹ (where R¹¹ represents a C1-C15 linear, C3-C15 branched, or C3-C15 cyclic alkyl group), or —O—C(═O)—R¹² (where R¹² represents a C1-C6 linear, C3-C6 branched, or C3-C6 cyclic alkyl group); and m represents an integer of 0 to 3.

The following structures are preferred examples of the polymerization unit of formula (10).

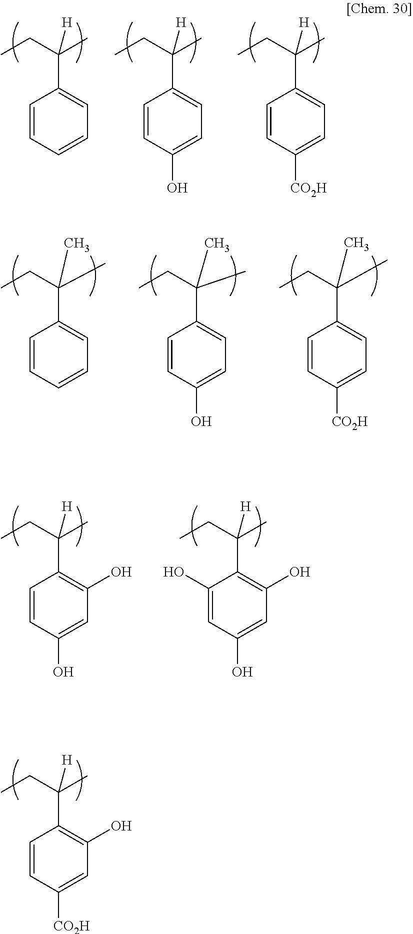

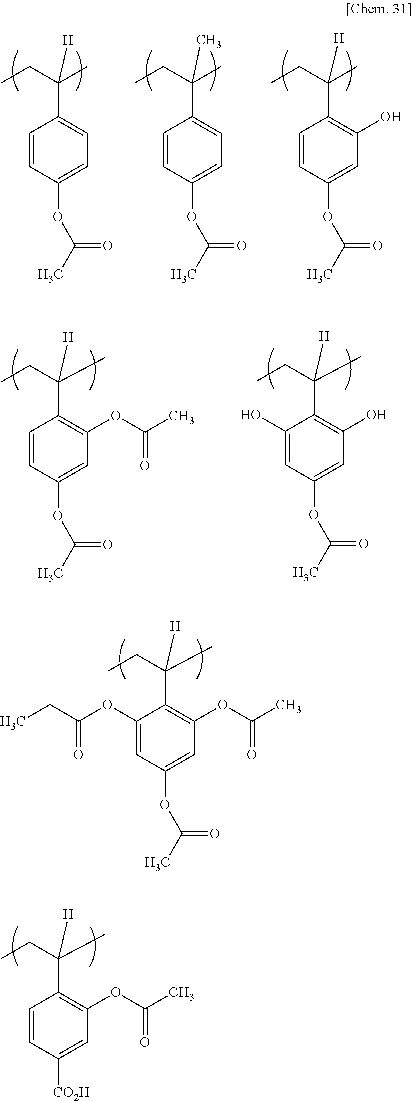

The polymerization unit of formula (10) wherein B is a hydroxy group or a carboxy group has solubility in an alkali developer. Thus, when it is desired to impart alkali developability to partition walls formed with the liquid-repellent agent (A) according to the first embodiment of the present disclosure, the polymer preferably contains a polymerization unit of formula (10) wherein B is a hydroxy group or a carboxy group.

The polymerization unit (a22) may have a structure represented by the following formula (11).

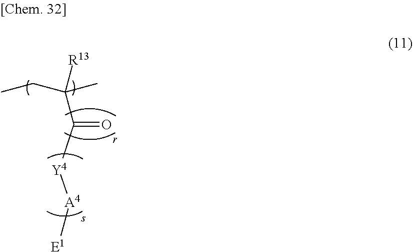

In formula (11), R¹³ represents a hydrogen atom or a methyl group.

In formula (11), A⁴ represents a divalent linking group and represents a C1-C10 linear, C3-C10 branched, or C3-C10 cyclic alkylene group in which any number of hydrogen atoms may be replaced with hydroxy groups or —O—C(═O)—CH₃.

When the divalent linking group A⁴ is a C1-C10 linear alkylene group, examples thereof include a methylene group, an ethylene group, a propylene group, an n-butylene group, an n-pentylene group, an n-hexalene group, an n-heptalene group, an n-octalene group, an n-nonalene group, and an n-decalene group.

When the divalent linking group A⁴ is a C3-C10 branched alkylene group, examples thereof include an isopropylene group, an isobutylene group, a sec-butylene group, a tert-butylene group, an isopentalene group, and an isohexalene group.

When the divalent linking group A⁴ is a C3-C10 cyclic alkylene group, examples thereof include disubstituted cyclopropanes, disubstituted cyclobutanes, disubstituted cyclopentanes, disubstituted cyclohexanes, disubstituted cycloheptanes, disubstituted cyclooctanes, disubstituted cyclodecanes, and disubstituted 4-tert-butylcyclohexanes.

When any number of hydrogen atoms in these alkylene groups are replaced with hydroxy groups, examples of such hydroxy group-substituted alkylene groups include a 1-hydroxyethylene group (—CH(OH)CH₂—), a 2-hydroxyethylene group (—CH₂CH(OH)—), a 1-hydroxy-n-propylene group, a 2-hydroxy-n-propylene group, a hydroxy-isopropylene group (—CH(CH₂OH)CH₂—), a 1-hydroxy-n-butylene group, a 2-hydroxy-n-butylene group, a hydroxy-sec-butylene group (—CH(CH₂OH)CH₂CH₂—), a hydroxy-isobutylene group (—CH₂CH(CH₂OH)CH₂—), and a hydroxy-tert-butylene group (—C(CH₂OH)(CH₃)CH₂—).

Also, when any number of hydrogen atoms in these alkylene groups are replaced with —O—C(═O)—CH₃, examples of such substituted alkylene groups include those in which the hydroxy groups of the hydroxy group-substituted alkylene groups exemplified above are replaced with —O—C(═O)—CH₃.

Of these, the divalent linking group A⁴ is preferably a methylene group, an ethylene group, a propylene group, an n-butylene group, an isobutylene group, a sec-butylene group, a cyclohexyl group, a 1-hydroxyethylene group (—CH(OH)CH₂—), a 2-hydroxyethylene group (—CH₂CH(OH)—), a 2-hydroxy-n-propylene group, a hydroxy-isopropylene group (—CH(CH₂OH)CH₂—), a 2-hydroxy-n-butylene group, or a hydroxy-sec-butylene group (—CH(CH₂OH)CH₂CH₂—); more preferably an ethylene group, a propylene group, a 1-hydroxyethylene group (—CH(OH)CH₂—), a 2-hydroxyethylene group (—CH₂CH(OH)—), a 2-hydroxy-n-propylene group, or a hydroxy-isopropylene group (—CH(CH₂OH)CH₂—); particularly preferably an ethylene group, a 1-hydroxyethylene group (—CH(OH)CH₂—), or a 2-hydroxyethylene group (—CH₂CH(OH)—).

In formula (11), Y⁴ represents a divalent linking group and represents —O— or —NH—, with —O— being more preferred.

In formula (11), r represents 0 or 1. When r is 0, (—C(═O)—) represents a single bond.

In formula (11), E¹ represents a hydroxy group, a carboxy group, or an oxirane group.

When E¹ is an oxirane group, examples thereof include an ethylene oxide group, a 1,2-propylene oxide group, and a 1,3-propylene oxide group. Preferred of these is an ethylene oxide group.

In formula (11), s represents 0 or 1. When s is 0, (—Y⁴—A⁴—) represents a single bond. When r is 0 and s is 0, the polymerization unit forms a structure in which E¹ is bonded to the main chain.

The following structures are preferred examples of the polymerization unit of formula (11).

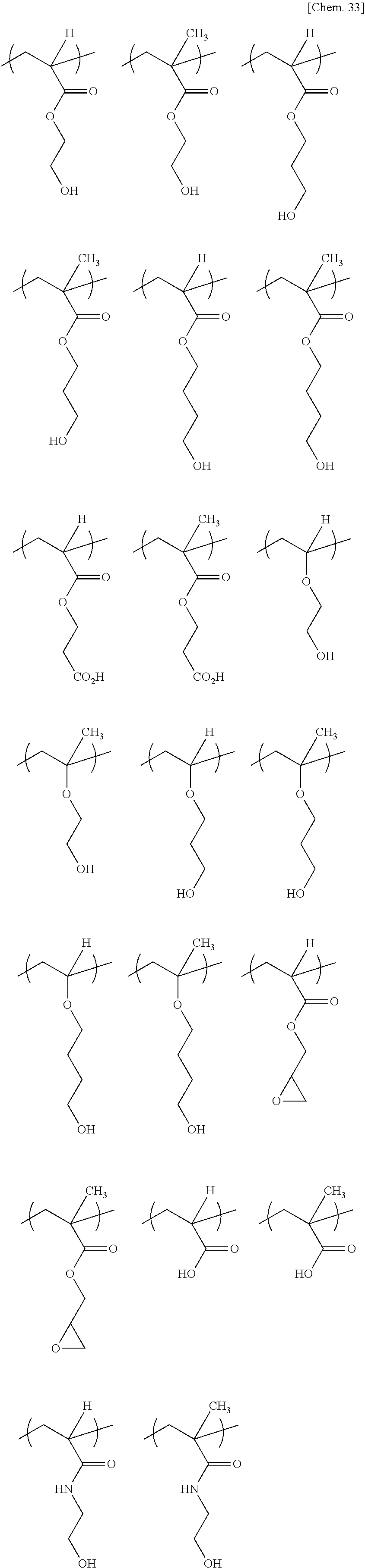

The polymerization unit of formula (11) wherein E¹ is a hydroxy group or a carboxy group has solubility in an alkali developer. Thus, when it is desired to impart alkali developability to partition walls formed with the liquid-repellent agent (A) according to the first embodiment of the present disclosure, the polymer preferably contains a polymerization unit of formula (11) wherein E¹ is a hydroxy group or a carboxy group.

The fluorine atom content of the polymer in the liquid-repellent agent (A) according to the first embodiment of the present disclosure is preferably 10 to 55 mass %, more preferably 10 to 30 mass %.

When the fluorine atom content of the polymer is within this range, the liquid-repellent agent (A) can be easily dissolved in a solvent. Moreover, partition walls formed with such a liquid-repellent agent (A) according to the first embodiment of the present disclosure have improved liquid repellency.

Herein, the term “fluorine atom content of the polymer” means the value calculated from the molar percentages of the monomers constituting the polymer measured by nuclear magnetic resonance spectroscopy (NMR), the molecular weights of the monomers constituting the polymer, and the amount of fluorine in each monomer.

The following describes a method of measuring the fluorine atom content when the polymer is a resin produced by polymerizing 1,1-bistrifluoromethylbutadiene, 4-hydroxystyrene, and 2-(perfluorohexyl)ethyl methacrylate.
(i) First, the polymer is measured by NMR to calculate the percentage of each constituent (molar percentage).
(ii) The molecular weight (Mw) of each constituent monomer of the polymer is multiplied by the molar percentage thereof, and the resulting values are added up to determine the total value. The weight percentage (wt %) of each constituent is calculated from the total value.

Here, the molecular weight of 1,1-bistrifluoromethylbutadiene is 190, the molecular weight of 1,1-bistrifluoromethylbutadiene is 120, and the molecular weight of 2-(perfluorohexyl)ethyl methacrylate is 432.
(iii) Next, the fluorine atom content of the constituent monomer containing a fluorine atom is calculated.
(iv) For each component, “[the fluorine atom content of the monomer]÷[the molecular weight (Mw) of the monomer]×[the weight percentage (wt %) thereof]” is calculated, and the resulting values are added up.
(v) The value obtained in (iv) is divided by the total value obtained in (ii) to calculate the fluorine atom content of the polymer.

The molecular weight of the polymer, expressed as the mass average molecular weight measured by gel permeation chromatography (GPC) using polystyrene standards, is preferably at least 1,000 but not more than 1,000,000, more preferably at least 2,000 but not more than 500,000, particularly preferably at least 3,000 but not more than 100,000. When the molecular weight is less than 1,000, the formed partition walls tend to have a lower strength. When the molecular weight is more than 1,000,000, it may be difficult to form partition walls due to the lack of solubility in solvents.

The dispersity (Mw/Mn) is preferably 1.01 to 5.00, more preferably 1.01 to 4.00, particularly preferably 1.01 to 3.00.

The polymer may be a random copolymer, an alternating copolymer, a block copolymer, or a graft copolymer. Preferably, the polymer is a random copolymer in order to disperse the respective characteristics appropriately rather than locally.

### Second Embodiment

A liquid-repellent agent (A) according to a second embodiment of the present disclosure contains a polymer containing: a polymerization unit (a1) derived from a hydrocarbon having an alkyl group in which at least one hydrogen atom is replaced with a fluorine atom and which may contain an ether-oxygen atom; and a polymerization unit (a21′) containing two or more ethylenically unsaturated double bonds.

The use of the liquid-repellent agent (A) according to the second embodiment of the present disclosure enables the production of partition walls that are less susceptible to reduction in liquid repellency even when subjected to oxygen plasma treatment or UV-ozone treatment.

As long as the liquid-repellent agent (A) according to the second embodiment of the present disclosure contains the polymerization unit (a21′) containing two or more ethylenically unsaturated double bonds, the polymerization unit (a1) may not contain any ethylenically unsaturated double bond or may contain one or more ethylenically unsaturated double bonds.

Moreover, in the liquid-repellent agent (A) according to the second embodiment of the present disclosure, the percentage of ethylenically unsaturated double bonds in the polymer is preferably 0.1 to 10 mass %, more preferably 0.5 to 3 mass % relative to the mass of the total polymer.

When the percentage is not lower than the lower limit value, the resistance to oxygen plasma treatment and UV-ozone treatment tends to improve. When the percentage is not higher than the upper limit value, a desired pattern tends to be easily formed.

Preferred structures of the polymerization unit (a1) in the liquid-repellent agent (A) according to the second embodiment of the present disclosure are as described for the preferred structures of the polymerization unit (a1) in the liquid-repellent agent (A) according to the first embodiment of the present disclosure.

Preferred structures of the polymerization unit (a21′) containing two or more ethylenically unsaturated double bonds in the liquid-repellent agent (A) according to the second embodiment of the present disclosure are as described for the preferred structures of the polymerization unit (a21′) containing two or more ethylenically unsaturated double bonds in the liquid-repellent agent (A) according to the first embodiment of the present disclosure.

### Third Embodiment

A curable composition according to a third embodiment of the present disclosure contains the liquid-repellent agent (A) according to the first embodiment and/or the liquid-repellent agent (A) of the second embodiment; a resin component (B) including an alkali-soluble resin (B1) and/or an alkali-soluble monomer (B2); and a photopolymerization initiator (C).

The use of the curable composition according to the third embodiment of the present disclosure, which contains the liquid-repellent agent (A) according to the first embodiment and/or the liquid-repellent agent (A) according to the second embodiment, enables the production of partition walls that are less susceptible to reduction in liquid repellency even when subjected to oxygen plasma treatment or UV-ozone treatment.

In the curable composition according to the third embodiment of the present disclosure, the amount of the polymer of the liquid-repellent agent (A) is preferably 0.1 to 50 mass %, more preferably 0.5 to 10 mass % relative to the mass of the total solids in the curable composition.

### Resin Component (B)

In the curable composition according to the third embodiment of the present disclosure, the resin component (B) includes an alkali-soluble resin (B1) and/or an alkali-soluble monomer (B2).

Due to the presence of the alkali-soluble resin (B1) and/or the alkali-soluble monomer (B2) in the curable composition according to the third embodiment of the present disclosure, the partition walls formed from the curable composition according to the third embodiment of the present disclosure can have a good shape.

Examples of the alkali-soluble resin (B1) include alkali-soluble novolac resins.

Alkali-soluble novolac resins can be produced by condensation of a phenol with an aldehyde in the presence of an acid catalyst.

Specific examples of the phenol include phenol, o-cresol, m-cresol, p-cresol, 2,3-dimethylphenol, 2,4-dimethylphenol, 2,5-dimethylphenol, 3,4-dimethylphenol, 3,5-dimethylphenol, 2,3,5-trimethylphenol, 3,4,5-trimethylphenol, resorcinol, 2-methylresorcinol, 4-ethylresorcinol, hydroquinone, methylhydroquinone, catechol, 4-methyl-catechol, pyrogallol, phloroglucinol, thymol, and isothymol. These phenols may be used alone or in combinations of two or more.

Specific examples of the aldehyde include formaldehyde, trioxane, paraformaldehyde, benzaldehyde, acetaldehyde, propylaldehyde, phenylacetaldehyde, α-phenylpropylaldehyde, β-phenylpropylaldehyde, o-hydroxybenzaldehyde, m-hydroxybenzaldehyde, p-hydroxybenzaldehyde, o-methylbenzaldehyde, m-methylbenzaldehyde, p-methylbenzaldehyde, nitrobenzaldehyde, furfural, glyoxal, glutaraldehyde, terephthalaldehyde, and isophthalaldehyde.

Specific examples of the acid catalyst include hydrochloric acid, nitric acid, sulfuric acid, phosphoric acid, phosphorous acid, formic acid, oxalic acid, acetic acid, methanesulfonic acid, diethyl sulfate, and p-toluenesulfonic acid. These acid catalysts may be used alone or in combinations of two or more.

Other examples of the alkali-soluble resin (B1) include acid-modified epoxy acrylates. Examples of commercially available acid-modified epoxy acrylates include CCR-1218H, CCR-1159H, CCR-1222H, CCR-1291H, CCR-1235, PCR-1050, TCR-1335H, UXE-3024, ZAR-1035, ZAR-2001H, ZFR-1185, and ZCR-1569H (trade names) available from Nippon Kayaku Co., Ltd.

The mass average molecular weight of the alkali-soluble resin (B1) is preferably 1,000 to 50,000, from the standpoint of the developability and resolution of the curable composition.

The amount of the alkali-soluble resin (B1) in the curable composition according to the third embodiment of the present disclosure is preferably at least 500 parts by mass but not more than 10,000 parts by mass, more preferably at least 1,000 parts by mass but not more than 7,000 parts by mass, relative to 100 parts by mass of the polymer in the liquid-repellent agent (A).

When the amount of the alkali-soluble resin (B1) is more than 10,000 parts by mass, the partition walls formed from the curable composition according to the third embodiment of the present disclosure tend to have insufficiently high liquid repellency after UV-ozone treatment or oxygen plasma treatment.

Examples of the alkali-soluble monomer (B2) include monomers having an acidic group and an ethylenic double bond. Monomers such as 2,2,2-triacryloyloxymethylethylphthalic acid are preferred.

### Photopolymerization Initiator (C)

In the curable composition according to the third embodiment of the present disclosure, any known photopolymerization initiator (C) can be used as long as it allows a monomer having a polymerizable double bond to be polymerized by high energy rays such as electromagnetic waves or electron beams.

The photopolymerization initiator (C) used may be a photo-radical initiator or a photoacid initiator. These may be used alone, or a photo-radical initiator and a photoacid initiator may be used in combination, or two or more photo-radical initiators or photoacid initiators may be used in admixture. Moreover, the use of the photopolymerization initiator (C) in combination with an additive enables living polymerization in some cases. The additive used may be a known additive.

Specifically, photo-radical initiators can be classified into: the intramolecular cleavage type in which the intramolecular bond can be cleaved by absorption of electromagnetic waves or electron beams to generate radicals; the hydrogen abstraction type that, when used in combination with a hydrogen donor such as a tertiary amine or ether, generates radicals, and other types. Either type can be used. Photo-radical initiators other than those listed above can also be used.

Specific examples of photo-radical initiators include benzophenone-based, acetophenone-based, diketone-based, acylphosphine oxide-based, quinone-based, and acyloin-based photo-radical initiators.

Specific examples of the benzophenone-based photo-radical initiators include benzophenone, 4-hydroxybenzophenone, 2-benzoylbenzoic acid, 4-benzoylbenzoic acid, 4,4′-bis(dimethylamino)benzophenone, and 4,4′-bis(diethylamino)benzophenone. Preferred of these are 2-benzoylbenzoic acid, 4-benzoylbenzoic acid, and 4,4′-bis(diethylamino)benzophenone.

Specific examples of the acetophenone-based photo-radical initiators include acetophenone, 2-(4-toluenesulfonyloxy)-2-phenylacetophenone, p-dimethylaminoacetophenone, 2,2′-dimethoxy-2-phenylacetophenone, p-methoxyacetophenone, 2-methyl-[4-(methylthio)phenyl]-2-morpholino-1-propanone, and 2-benzyl-2-dimethylamino-1-(4-morpholinophenyl)-butan-1-one. Preferred of these is p-dimethylaminoacetophenone or p-methoxyacetophenone.

Specific examples of the diketone-based photo-radical initiators include 4,4′-dimethoxybenzil, methyl benzoylformate, and 9,10-phenanthrenequinone. Preferred of these is 4,4′-dimethoxybenzil or methyl benzoylformate.

Specific examples of the acylphosphine oxide-based photo-radical initiators include bis(2,4,6-trimethylbenzoyl)-phenylphosphine oxide.

Specific examples of the quinone-based photo-radical initiators include anthraquinone, 2-ethylanthraquinone, camphorquinone, and 1,4-naphthoquinone. Preferred of these is camphorquinone or 1,4-naphthoquinone.

Specific examples of the acyloin-based photo-radical initiators include benzoin, benzoin methyl ether, benzoin ethyl ether, and benzoin isopropyl ether. Preferred of these is benzoin or benzoin methyl ether.

Preferred are benzophenone-based, acetophenone-based, and diketone-based photo-radical initiators. More preferred are benzophenone-based photo-radical initiators.

Examples of preferred commercially available photo-radical initiators include Irgacure 127, Irgacure 184, Irgacure 369, Irgacure 651, Irgacure 819, Irgacure 907, Irgacure 2959, Irgacure OXE-01, Darocur 1173, and Lucirin TPO (trade names) available from BASF. More preferred of these is Irgacure 651 or Irgacure 369.

Specifically, a photoacid initiator is an onium salt of a pair of a cation and an anion, the cation being at least one selected from the group consisting of an aromatic sulfonic acid, an aromatic iodonium, an aromatic diazonium, an aromatic ammonium, thianthrenium, thioxanthonium, and (2,4-cyclopentadien-1-yl) (1-methylethylbenzene)-iron, the anion being at least one selected from the group consisting of tetrafluoroborate, hexafluorophosphate, hexafluoroantimonate, and pentafluorophenylborate.

Particularly preferred of these are bis[4-(diphenylsulfonio)phenyl]sulfide bishexafluorophosphate, bis[4-(diphenylsulfonio)phenyl]sulfide tetrakis(pentafluorophenyl)borate, and diphenyliodonium hexafluorophosphate.

Examples of commercially available photoacid initiators include CPI-100P, CPI-110P, CPI-101A, CPI-200K, and CPI-210S (trade names) available from San-Apro Ltd.; CYRACURE Photoinitiator UVI-6990, CYRACURE Photoinitiator UVI-6992, and CYRACURE Photoinitiator UVI-6976 (trade names) available from Dow Chemical Japan Limited; ADEKA OPTOMER SP-150, ADEKA OPTOMER SP-152, ADEKA OPTOMER SP-170, ADEKA OPTOMER SP-172, and ADEKA OPTOMER SP-300 (trade names) available from ADEKA CORPORATION; CI-5102 and CI-2855 (trade names) available from Nippon Soda Co., Ltd.; SAN AID SI-60L, SAN AID SI-80L, SAN AID SI-100L, SAN AID SI-110L, SAN AID SI-180L, SAN AID SI-110, and SAN AID SI-180 (trade names) available from Sanshin Chemical Industry Co. Ltd.; Esacure 1064 and Esacure 1187 (trade names) available from Lamberti; and Irgacure 250 (trade name) available from Ciba Specialty Chemicals.

The amount of the photopolymerization initiator (C) is preferably at least 0.1 parts by mass but not more than 30 parts by mass, more preferably at least 1 part by mass but not more than 20 parts by mass, relative to 100 parts by mass of the combined mass of the polymer in the liquid-repellent agent (A) and the resin component (B). When the amount of the photopolymerization initiator is less than 0.1 parts by mass, the resulting crosslinking effect tends to be insufficient. When the amount thereof is more than 30 parts by mass, the resolution and sensitivity tend to decrease.

In the curable composition according to the third embodiment of the present disclosure, the liquid-repellent agent (A), the resin component (B), and the photopolymerization initiator (C) may be dissolved in a solvent.

Any solvent may be used, and examples include ketones, alcohols, polyhydric alcohols and their derivatives, ethers, esters, aromatic solvents, and fluorine solvents. These may be used alone or in admixtures of two or more.

Specific examples of the ketones include acetone, methyl ethyl ketone, cyclopentanone, cyclohexanone, methyl isoamyl ketone, 2-heptanone, cyclopentanone, methyl isobutyl ketone, methyl isopentyl ketone, and 2-heptanone.

Specific examples of the alcohols include isopropanol, butanol, isobutanol, n-pentanol, isopentanol, tert-pentanol, 4-methyl-2-pentanol, 3-methyl-3-pentanol, 2,3-dimethyl-2-pentanol, n-hexanol, n-heptanol, 2-heptanol, n-octanol, n-decanol, s-amyl alcohol, t-amyl alcohol, isoamyl alcohol, 2-ethyl-1-butanol, lauryl alcohol, hexyl decanol, and oleyl alcohol.

Specific examples of the polyhydric alcohols and their derivatives include ethylene glycol, ethylene glycol monoacetate, ethylene glycol dimethyl ether, diethylene glycol, diethylene glycol dimethyl ether, diethylene glycol monoacetate, propylene glycol, propylene glycol monoacetate, propylene glycol monomethyl ether (PGME), propylene glycol monoethyl ether, propylene glycol monopropyl ether, propylene glycol monobutyl ether, propylene glycol monomethyl ether acetate (PGMEA), and monomethyl ether, monoethyl ether, monopropyl ether, monobutyl ether, and monophenyl ether of dipropylene glycol or dipropylene glycol monoacetate.

Specific examples of the ethers include diethyl ether, diisopropyl ether, tetrahydrofuran, dioxane, and anisole.

Specific examples of the esters include methyl lactate, ethyl lactate (EL), methyl acetate, ethyl acetate, butyl acetate, methyl pyruvate, ethyl pyruvate, methyl methoxypropionate, ethyl ethoxypropionate, and γ-butyrolactone.

Examples of the aromatic solvents include xylene and toluene.

Examples of the fluorine solvents include chlorofluorocarbons, hydrochlorofluorocarbons, hydrofluorocarbons, perfluoro compounds, and hexafluoroisopropyl alcohol.

Other solvents such as terpene-based petroleum naphtha solvents and paraffinic solvents, which are high-boiling-point weak solvents, can also be used to enhance coating properties.

Of these, the solvent is preferably at least one selected from the group consisting of methyl ethyl ketone, cyclohexanone, methyl isoamyl ketone, 2-heptanone, ethylene glycol, ethylene glycol dimethyl ether, ethylene glycol monoacetate, diethylene glycol, diethylene glycol monoacetate, diethylene glycol dimethyl ether, propylene glycol, propylene glycol monoacetate, propylene glycol monomethyl ether (PGME), propylene glycol monomethyl ether acetate (PGMEA), dipropylene glycol, dipropylene glycol monoacetate monomethyl ether, dipropylene glycol monoacetate monoethyl ether, dipropylene glycol monoacetate monopropyl ether, dipropylene glycol monoacetate monobutyl ether, dipropylene glycol monoacetate monophenyl ether, 1,4-dioxane, methyl lactate, ethyl lactate, methyl acetate, ethyl acetate, butyl acetate, methyl methoxypropionate, ethyl ethoxypropionate, γ-butyrolactone, and hexafluoroisopropyl alcohol. More preferred are methyl ethyl ketone, propylene glycol monomethyl ether acetate (PGMEA), propylene glycol monomethyl ether (PGME), cyclohexanone, ethyl lactate, butyl acetate, and γ-butyrolactone.

The amount of the solvent in the curable composition according to the third embodiment of the present disclosure is preferably in the range of at least 50 parts by mass but not more than 2,000 parts by mass, more preferably at least 100 parts by mass but not more than 1,000 parts by mass, relative to 100 parts by mass of the combined mass of the polymer in the liquid-repellent agent (A) and the resin component (B). Controlling the amount of the solvent makes it easy to control the thickness of the film of the curable composition applied to a substrate.

The curable composition according to the third embodiment of the present disclosure may contain a crosslinking agent (D), a polymerization inhibitor (E), an ultraviolet absorber (F), and a chain transfer agent (G), in addition to the liquid-repellent agent (A), the resin component (B), and the photopolymerization initiator (C) as essential components.

### Crosslinking Agent (D)

Known crosslinking agents (D) can be used. Specific examples include compounds obtained by reacting an amino group-containing compound such as melamine, acetoguanamine, benzoguanamine, urea, ethylene urea, propylene urea, or glycoluril with formaldehyde or formaldehyde and a lower alcohol to replace the hydrogen atom of the amino group with a hydroxymethyl group or a lower alkoxymethyl group; polyfunctional epoxy compounds; polyfunctional oxetane compounds; polyfunctional isocyanate compounds; and polyfunctional acrylate compounds. Here, those containing melamine are referred to as melamine-based crosslinking agents, those containing urea are referred to as urea-based crosslinking agents, those containing an alkylene urea such as ethylene urea or propylene urea are referred to as alkylene urea-based crosslinking agents, and those containing glycoluril are referred to as glycoluril-based crosslinking agents. These crosslinking agents may be used alone or in admixtures of two or more.

Preferably, the crosslinking agent (D) is at least one selected from these crosslinking agents, particularly preferably glycoluril-based crosslinking agents and polyfunctional acrylate compounds.

Examples of the melamine-based crosslinking agents include hexamethoxymethylmelamine, hexaethoxymethylmelamine, hexapropoxymethylmelamine, and hexabutoxybutylmelamine. Preferred of these is hexamethoxymethylmelamine.

Examples of the urea-based crosslinking agents include bismethoxymethylurea, bisethoxymethylurea, bispropoxymethylurea, and bisbutoxymethylurea. Preferred of these is bismethoxymethylurea.

Examples of the alkylene urea-based crosslinking agents include ethylene urea-based crosslinking agents such as mono- and/or di-hydroxymethylated ethylene urea, mono-and/or di-methoxymethylated ethylene urea, mono- and/or di-ethoxymethylated ethylene urea, mono- and/or di-propoxymethylated ethylene urea, and mono- and/or di-butoxymethylated ethylene urea; propylene urea-based crosslinking agents such as mono- and/or di-hydroxymethylated propylene urea, mono- and/or di-methoxymethylated propylene urea, mono- and/or di-ethoxymethylated propylene urea, mono- and/or di-propoxymethylated propylene urea, and mono- and/or di-butoxymethylated propylene urea; 1,3-di(methoxymethyl)-4,5-dihydroxy-2-imidazolidinone, and 1,3-di(methoxymethyl)-4,5-dimethoxy-2-imidazolidinone.

Examples of the glycoluril-based crosslinking agents include mono-, di-, tri-, and/or tetra-hydroxymethylated glycoluril; mono-, di-, tri-, and/or tetra-methoxymethylated glycoluril; mono-, di-, tri-, and/or tetra-ethoxymethylated glycoluril; mono-, di-, tri-, and/or tetra-propoxymethylated glycoluril; and mono-, di-, tri-, and/or tetra-butoxymethylated glycoluril.

Examples of the polyfunctional acrylate compounds include polyfunctional acrylates (e.g., A-TMM-3, A-TMM-3L, A-TMM-3LM-N, A-TMPT, and AD-TMP (trade names) available from Shin-Nakamura Chemical Co., Ltd.); polyethylene glycol diacrylates (e.g., A-200, A-400, and A-600 (trade names) available from Shin-Nakamura Chemical Co., Ltd.); urethane acrylates (e.g., UA-122P, UA-4HA, UA-6HA, UA-6LPA, UA-11003H, UA-53H, UA-4200, UA-200PA, UA-33H, UA-7100, and UA-7200 (trade names) available from Shin-Nakamura Chemical Co., Ltd.); and pentaerythritol tetraacrylate.

The following are preferred examples of polyfunctional acrylate compounds.

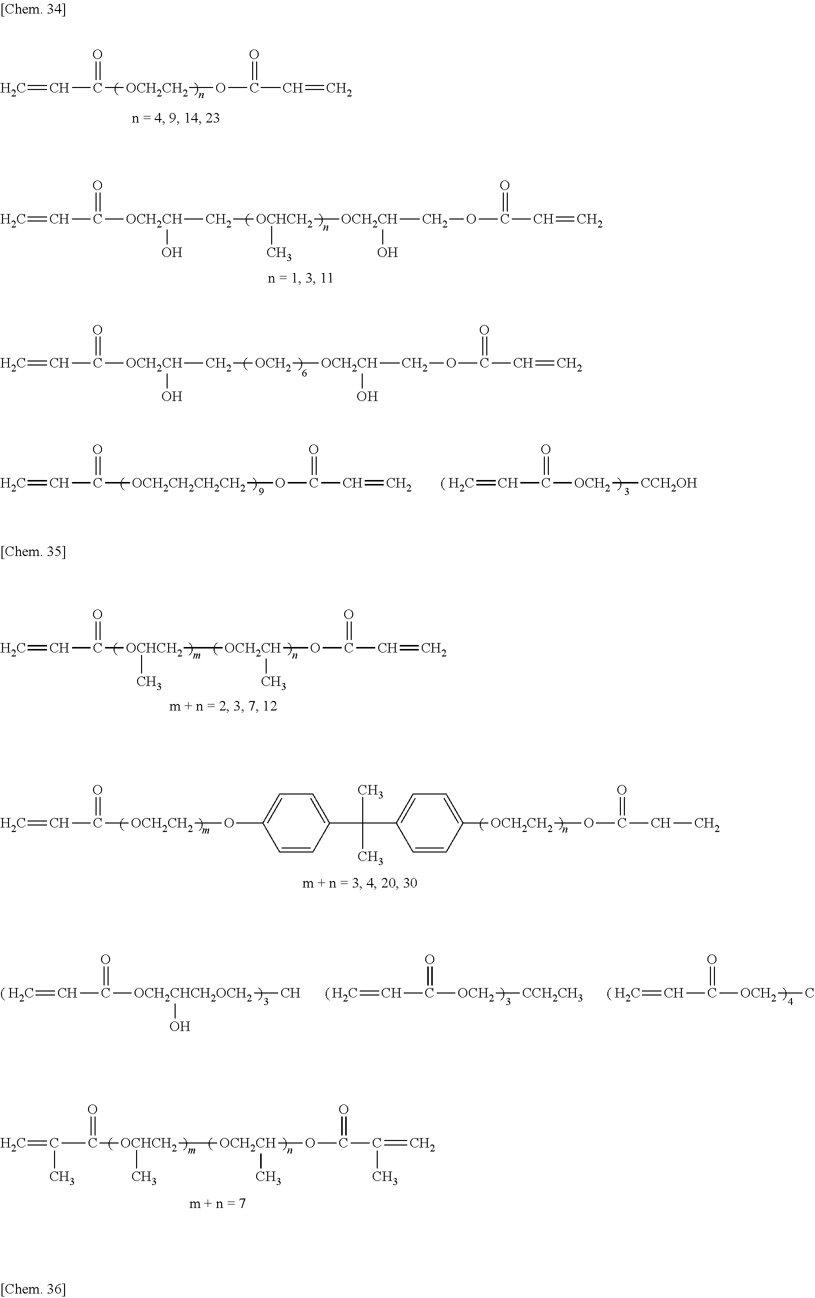

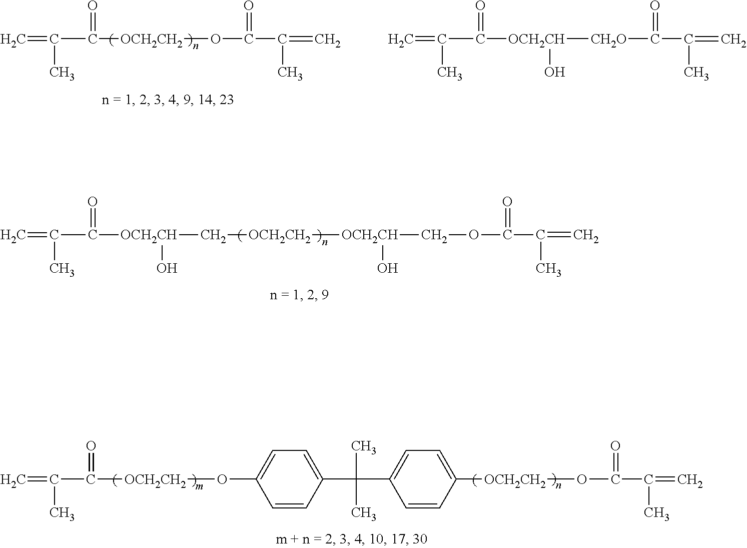

The amount of the crosslinking agent is preferably at least 10 parts by mass but not more than 300 parts by mass, more preferably at least 50 parts by mass but not more than 200 parts by mass, relative to 100 parts by mass of the combined mass of the polymer in the liquid-repellent agent (A) and the resin component (B).

When the amount of the crosslinking agent is less than 10 parts by mass, the resulting crosslinking effect tends to be insufficient. When the amount thereof is more than 300 parts by mass, the resolution and sensitivity tend to decrease.

### Polymerization Inhibitor (E)

Non-limiting examples of the polymerization inhibitor (E) include o-cresol, m-cresol, p-cresol, 6-t-butyl-2,4-xylenol, 2,6-di-t-butyl-p-cresol, hydroquinone, catechol, 4-t-butylpyrocatechol, 2,5-bistetramethylbutylhydroquinone, 2,5-di-t-butylhydroquinone, p-methoxyphenol, 1,2,4-trihydroxybenzene, 1,2-benzoquinone, 1,3-benzoquinone, 1,4-benzoquinone, leucoquinizarin, phenothiazine, 2-methoxyphenothiazine, tetraethylthiuram disulfide, 1,1-diphenyl-2-picrylhydrazyl, and 1,1-diphenyl-2-picrylhydrazine.

Examples of commercially available polymerization inhibitors include N,N′-di-2-naphthyl-p-phenylenediamine (trade name, NONFLEX F), N,N-diphenyl-p-phenylenediamine (trade name, NONFLEX H), 4,4′-bis(a,a-dimethylbenzyl)diphenylamine (trade name, NONFLEX DCD), 2,2′-methylene-bis(4-methyl-6-tert-butylphenol) (trade name, NONFLEX MBP), and N-(1-methylheptyl)-N′-phenyl-p-phenylenediamine (trade name, OZONONE 35), all of which are available from Seiko Chemical Co., Ltd., and ammonium N-nitrosophenylhydroxyamine (trade name, Q-1300) and N-nitrosophenylhydroxyamine aluminum salt (trade name, Q-1301), both of which are available from FUJIFILM Wako Pure Chemical Corporation.

### Ultraviolet Absorber (F)

Examples of the ultraviolet absorber (F) include salicylic acid-based ultraviolet absorbers, benzophenone-based ultraviolet absorbers, triazole-based ultraviolet absorbers, and triazine-based ultraviolet absorbers.

The amount of the ultraviolet absorber is preferably 0.01 to 15 mass %, more preferably 1 to 3 mass % based on the total solids of the photosensitive resin composition.

### Chain Transfer Agent (G)

Examples of the chain transfer agent include: mercaptans such as n-butylmercaptan, n-dodecylmercaptan, t-butylmercaptan, ethyl thioglycolate, 2-ethylhexyl thioglycolate, and 2-mercaptoethanol; and alkyl halides such as chloroform, carbon tetrachloride, and carbon tetrabromide.

The amount of the chain transfer agent is preferably 0.01 to 15 mass %, more preferably 1 to 5 mass % based on the total solids of the photosensitive resin composition.

The curable composition according to the third embodiment of the present disclosure may further contain a naphthoquinone diazide group-containing compound, a basic compound, and other additives.

### Naphthoquinone Diazide Group-Containing Compound

When the curable composition according to the third embodiment of the present disclosure contains a naphthoquinone diazide group-containing compound, the partition walls formed from the curable composition according to the third embodiment of the present disclosure can have a good shape.

Any naphthoquinone diazide group-containing compound can be used, including those commonly used as photosensitive components of resist compositions for i-rays.

Specific examples of the naphthoquinone diazide group-containing compound include naphthoquinone-1,2-diazide-4-sulfonate compounds, naphthoquinone-1,2-diazide-5-sulfonate compounds, naphthoquinone-1,2-diazide-6-sulfonate compounds, naphthoquinone-1,2-diazide sulfonate compounds, orthobenzoquinone diazide sulfonate compounds, and orthoanthraquinone diazide sulfonate compounds. Preferred of these are naphthoquinone-1,2-diazide-4-sulfonate compounds, naphthoquinone-1,2-diazide-5-sulfonate compounds, and naphthoquinone-1,2-diazide-6-sulfonate compounds, because they have excellent solubility. These compounds may be used alone or in admixtures of two or more.

The amount of the naphthoquinone diazide group-containing compound in the curable composition according to the third embodiment of the present disclosure is preferably 10 parts by mass to 60 parts by mass, more preferably 20 parts by mass to 50 parts by mass, relative to 100 parts by mass of the combined mass of the polymer in the liquid-repellent agent (A) and the resin component (B). With more than 60 parts by weight of the naphthoquinone diazide group-containing compound, the curable composition tends to provide less sensitivity.

### Basic Compound

The basic compound serves to delay the diffusion rate of the acid generated by the photoacid generator as the acid diffuses into the film of the curable composition according to the third embodiment of the present disclosure.

The presence of the basic compound makes it possible to control the acid diffusion distance and improve the shape of the partition walls.

The presence of the basic compound also makes it possible to stably form partition walls with a desired accuracy because the partition walls are less likely to deform even when the partition walls formed are left to stand for a long time before being exposed.

Examples of the basic compound include aliphatic amines, aromatic amines, heterocyclic amines, and aliphatic polycyclic amines. Preferred of these are aliphatic amines, specific examples of which include secondary or tertiary aliphatic amines and alkyl alcohol amines. These basic compounds may be used alone or in admixtures of two or more.

Examples of the aliphatic amines include alkylamines or alkyl alcohol amines in which at least one hydrogen atom of ammonia (NH₃) is replaced with a C12 or lower alkyl group or hydroxyalkyl group. Specific examples include trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decanylamine, tri-n-dodecylamine, dimethylamine, diethylamine, di-n-propylamine, di-n-butylamine, di-n-pentylamine, di-n-hexylamine, di-n-heptylamine, di-n-octylamine, di-n-nonylamine, di-n-decanylamine, di-n-dodecylamine, dicyclohexylamine, methylamine, ethylamine, n-propylamine, n-butylamine, n-pentylamine, n-hexylamine, n-heptylamine, n-octylamine, n-nonylamine, n-decanylamine, n-dodecylamine, diethanolamine, triethanolamine, diisopropanolamine, triisopropanolamine, di-n-octanolamine, and tri-n-octanolamine.

Preferred of these are dialkylamines, trialkylamines, and alkyl alcohol amines. More preferred are alkyl alcohol amines. Particularly preferred of these alkyl alcohol amines is triethanolamine or triisopropanolamine.

Examples of the aromatic amines and heterocyclic amines include aniline and aniline derivatives such as N-methylaniline, N-ethylaniline, N-propylaniline, N,N-dimethylaniline, 2-methylaniline, 3-methylaniline, 4-methylaniline, ethylaniline, propylaniline, trimethylaniline, 2-nitroaniline, 3-nitroaniline, 4-nitroaniline, 2,4-dinitroaniline, 2,6-dinitroaniline, 3,5-dinitroaniline, and N,N-dimethyltoluidine; heterocyclic amines such as 1,5-diazabicyclo[4.3.0]non-5-en, 1,8-diazabicyclo[5.4.0]undec-7-en, 1,4-diazabicyclo[2.2.2]octane, pyridine, bipyridine, 4-dimethylaminopyridine, hexamethylenetetramine, and 4,4-dimethylimidazoline; hindered amines such as bis(1,2,2,6,6-pentamethyl-4-piperidyl)sebacate; alcoholic nitrogen-containing compounds such as 2-hydroxypyridine, aminocresol, 2,4-quinolinediol, 3-indolemethanol hydrate, monoethanolamine, diethanolamine, triethanolamine, N-ethyldiethanolamine, N,N-diethylethanolamine, triisopropanolamine, 2,2′-iminodiethanol, 2-aminoethanol, 3-amino-1-propanol, 4-amino-1-butanol, 4-(2-hydroxyethyl)morpholine, 2-(2-hydroxyethyl)pyridine, 1-(2-hydroxyethyl)piperazine, and 1-[2-(2-hydroxyethoxy)ethyl]piperazine; and picoline, lutidine, pyrrole, piperidine, piperazine, indole, hexamethylenetetramine, etc.

The amount of the basic compound in the curable composition according to the third embodiment of the present disclosure is preferably 0.001 parts by mass to 2 parts by mass, more preferably 0.01 parts by mass to 1 part by mass, relative to 100 parts by mass of the combined mass of the polymer in the liquid-repellent agent (A) and the resin component (B). When the amount of the basic compound is less than 0.001 parts by mass, the resulting effect thereof as an additive tends to be insufficient. When the amount thereof is more than 2 parts by mass, the resolution and sensitivity tend to decrease.

The curable composition according to the third embodiment of the present disclosure may contain other additives if necessary. Examples of other additives include various additives such as dissolution inhibitors, plasticizers, stabilizers, colorants, surfactants, thickeners, leveling agents, defoamers, compatibilizers, adhesives, and antioxidants.

These other additives may be known ones.

The curable composition according to the third embodiment of the present disclosure is preferably used for forming partition walls.

As described above, the use of the curable composition according to the third embodiment of the present disclosure enables the production of partition walls that are less susceptible to reduction in liquid repellency even when subjected to oxygen plasma treatment or UV-ozone treatment.

Moreover, a cured product of the curable composition according to the third embodiment of the present disclosure is one aspect of the present disclosure.

Furthermore, a partition wall including a cured product of the curable composition according to the third embodiment of the present disclosure is one aspect of the present disclosure.

Additionally, an organic electroluminescent element including the partition wall of the present disclosure is another aspect of the present disclosure.

### Fourth Embodiment

In the following, a method of producing a fluorine-containing coating film according to a fourth embodiment of the present disclosure is described.

The method of producing a fluorine-containing coating film according to the fourth embodiment of the present disclosure includes (1) a mixing step, (2) an application step, and (3) a curing step.

Each step is described below.

### (1) Mixing Step

In this step, the liquid-repellent agent (A) according to the first embodiment or the liquid-repellent agent (A) according to the second embodiment, a resin component (B) including an alkali-soluble resin (B1) and/or an alkali-soluble monomer (B2), and a photopolymerization initiator (C) are mixed to prepare a curable composition.

In other words, the curable composition according to the third embodiment is prepared in this step.

The preferred constituents contained in the curable composition have already been described, and thus are not described here.

### (2) Application Step

Next, the curable composition is applied to a substrate.

Any application method may be used, including spin coating and other known methods.

Any substrate may be used, including silicon wafers, metals, glass, ITO substrates, substrates containing metal oxides, synthetic resins (polyimide, polycarbonate, polyester), etc.

A luminescent layer may be formed on the substrate. The luminescent layer is preferably formed of an organic electroluminescent material, a LED material such as a mini-LED, a micro-LED, or a nano-LED, or a quantum dot luminescent material.

An organic or inorganic film may be provided between the substrate and the luminescent layer. For example, an anti-reflective film or an underlayer of a multilayer resist may be provided.

Moreover, a drive circuit or a planarizing layer may be formed between the substrate and the luminescent layer.

Examples of the planarizing layer include TFT planarizing layers.

Also, when the luminescent layer is formed of a LED material, an electrode may be formed between the substrate and the luminescent layer.

When the luminescent layer is disposed on the substrate, the substrate may be washed in advance. For example, the substrate may be washed with ultrapure water, acetone, alcohol (methanol, ethanol, or isopropyl alcohol), or other solvent.

Next, the curable composition is formed into a coating film by heating.

The heating conditions are not limited, but are preferably at 80 to 100° C. for 60 to 200 seconds.

This can remove the solvents and the like from the curable composition.

### (3) Curing Step

In the curing step, after the application step, the coating film formed of the curable composition is cured by irradiation with high energy rays. This produces a fluorine-containing coating film.

The high energy rays are preferably at least one type of rays selected from the group consisting of ultraviolet rays, gamma rays, X-rays, and a-rays.

The exposure of the high energy rays is preferably at least 1 mJ/cm² but not more than 200 mJ/cm², more preferably at least 10 mJ/cm² but not more than 100 mJ/cm².

The method of producing a fluorine-containing coating film of the present disclosure may include any other step as long as the method includes curing the coating film by irradiation with high energy rays. For example, the method may include the following steps.

In irradiating the coating film with high energy rays in the method of producing a fluorine-containing coating film of the present disclosure, a desired photomask may be set in an exposure device, and the coating film may be exposed to high energy rays through the photomask.

In this case, the coating film after the exposure is developed in an alkali aqueous solution to form a fluorine-containing coating film provided with a predetermined pattern having recesses. Specifically, the unexposed portions of the coating film are dissolved in an alkali aqueous solution to form a fluorine-containing coating film provided with a predetermined pattern.

The alkali aqueous solution may be a tetramethylammonium hydroxide (TMAH) aqueous solution, a tetrabutylammonium hydroxide (TBAH) aqueous solution, sodium hydroxide, potassium hydroxide, or other aqueous solution.

When the alkali aqueous solution is a tetramethylammonium hydroxide (TMAH) aqueous solution, the concentration thereof is preferably at least 0.1 mass % but not more than 5 mass %, more preferably at least 2 mass % but not more than 3 mass %.

Any known development method can be used, such as dipping, paddling, or spraying.

The development time is preferably at least 10 seconds but not more than 3 minutes, more preferably at least 30 seconds but not more than 2 minutes.

The development may optionally be followed by a step of washing the partition walls with deionized water or the like. Regarding the washing method and washing time, washing for at least 10 seconds but not more than 3 minutes is preferred, and washing for at least 30 seconds but not more than 2 minutes is more preferred.

A fluorine-containing coating film can be produced by the method described above.

This fluorine-containing coating film functions as partition walls to avoid mixing of ink droplets when ink is dropped into the recesses of the predetermined pattern.

The fluorine-containing coating film produced in this manner may be subjected to UV-ozone treatment or oxygen plasma treatment to remove the organic matter remaining on the coating film and reduce uneven wetting.

The fluorine-containing coating film is less susceptible to reduction in liquid repellency even when subjected to UV-ozone treatment or oxygen plasma treatment because it is formed from the curable composition according to the third embodiment of the present disclosure containing the liquid-repellent agent (A) according to the first embodiment of the present disclosure and/or the liquid-repellent agent (A) according to the second embodiment of the present disclosure.

The UV-ozone treatment may be performed using an UV-ozone treatment device (available from Sen Lights Corporation, model number: PL17-110), for example.

The oxygen plasma treatment may be performed using an oxygen plasma treatment device (available from Yamato Scientific Co., Ltd., model number: Plasma Dry Cleaner PDC210) at an oxygen gas flow rate of 30 cc/min and an output of 300 W.

The following fluorine-containing coating films, as fluorine-containing coating films that are less susceptible to reduction in liquid repellency after the treatment under the above-described conditions, are aspects of the present disclosure.

A fluorine-containing coating film formed on a substrate, wherein the value of the contact angle of the fluorine-containing coating film with propylene glycol monomethyl ether acetate after oxygen plasma treatment for 30 minutes is 95% to 100% of the value of the contact angle of the fluorine-containing coating film with propylene glycol monomethyl ether acetate before the oxygen plasma treatment.

The oxygen plasma treatment herein means treatment performed using an oxygen plasma treatment device (available from Yamato Scientific Co., Ltd., model number: Plasma Dry Cleaner PDC210) at an oxygen gas flow rate of 30 cc/min and an output of 300 W for 30 minutes.

A fluorine-containing coating film formed on a substrate, wherein the value of the contact angle of the fluorine-containing coating film with propylene glycol monomethyl ether acetate after UV-ozone treatment for 30 minutes is 95% to 100% of the value of the contact angle of the fluorine-containing coating film with propylene glycol monomethyl ether acetate before the UV-ozone treatment.

The UV-ozone treatment herein means treatment performed using an UV-ozone treatment device (available from Sen Lights Corporation, model number: PL17-110)) for 30 minutes.

### EXAMPLES

Hereinafter, examples that specifically disclose embodiments of the present disclosure are described. It should be noted that the present disclosure is not limited to these embodiments.

### 1. Production of Polymer

### (Measurement of Molar Ratio of Each Polymerization Unit) NMR

The molar ratio of each polymerization unit of the polymer was determined from the measurements of ¹H-NMR, ¹⁹F-NMR, or ¹³C-NMR.

### (Measurement of Molecular Weight of Polymer) GPC

The weight average molecular weight Mw and molecular weight dispersity (Mw/Mn: the ratio of the weight average molecular weight Mw to the number average molecular weight Mn) of the polymer were measured by high performance gel permeation chromatography (hereinafter sometimes referred to as GPC; model: HLC-8320 GPC available from Tosoh Corporation) with one ALPHA-M column and one ALPHA-2500 column (both available from Tosoh Corporation) connected in series using tetrahydrofuran (THF) as a developing solvent. The detector used was a refractive index difference detector.

### 2. Synthesis of Polymer

### Synthesis of Polymer Precursor 1

A 300 ml glass flask equipped with a stirrer was charged at room temperature (about 20° C.) with 4.3 parts by mass of 1,1-bis(trifluoromethyl)-1,3-butadiene (available from Central Glass Co., Ltd., hereinafter referred to as BTFBE), 2.7 parts by mass of 4-acetoxystyrene (product of Tokyo Chemical Industry Co., Ltd., hereinafter referred to as p-AcO-St), 21.4 parts by mass of 2-(perfluorobutyl)ethyl methacrylate (product of Tokyo Chemical Industry Co., Ltd., hereinafter referred to as MA-C4F), 6.1 parts by mass of 2-hydroxyethyl methacrylate (product of Tokyo Chemical Industry Co., Ltd., hereinafter referred to as HEMA), and 36.9 parts by mass of methyl ethyl ketone (hereinafter referred to as MEK). Then, 2.46 parts by mass of 2,2′-azobis(2-methylbutyronitrile) (product of Tokyo Chemical Industry Co., Ltd., hereinafter referred to as AIBN) was added and the mixture was degassed with stirring.

Subsequently, the flask was purged with nitrogen gas, the temperature inside the flask was raised to 79° C., and then a reaction was performed overnight. To the reaction system was dropped 250 parts by mass of n-heptane, whereby a white precipitate was obtained. This precipitate was filtered out and dried under reduced pressure at a temperature of 45° C. to give a polymer precursor 1 as a white solid with a yield of 88%.

### NMR Measurement Results

The ratio of each polymerization unit of the polymer precursor 1, expressed as the molar ratio, was as follows: BTFBE-derived polymerization unit:p-AcO-St-derived polymerization unit:MA-C4F-derived polymerization unit:HEMA-derived polymerization unit=15:11:43:31.

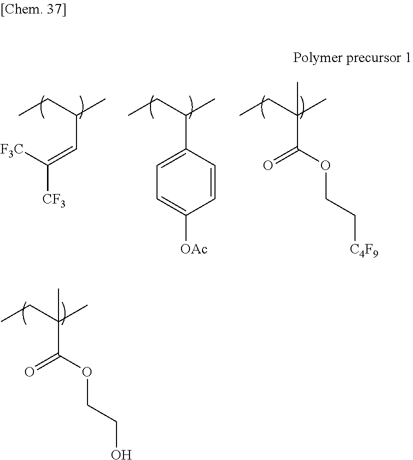

### GPC Measurement Results

### Mw=7,201, Mw/Mn=1.4

### Synthesis of Polymer Precursor 2

A 300 ml glass flask equipped with a stirrer was charged at room temperature (about 20° C.) with 11 parts by mass of vinylbenzoic acid (product of Tokyo Chemical Industry Co., Ltd., hereinafter referred to as VBA), 43 parts by mass of 2-(perfluorohexyl)ethyl methacrylate (product of Tokyo Chemical Industry Co., Ltd., hereinafter referred to as MA-C6F), 13 parts by mass of HEMA, and 75 parts by mass of MEK. Then, 1.6 parts by mass of AIBN was added and the mixture was degassed with stirring. Subsequently, the flask was purged with nitrogen gas, the temperature inside the flask was raised to 75° C., and then a reaction was performed overnight. To the reaction system was dropped 400 parts by mass of n-heptane, whereby a transparent viscous substance precipitated out. This viscous substance was isolated by decantation and dried under reduced pressure at 60° C. to give a polymer precursor 2 a transparent viscous substance with a yield of 83%.

### NMR Measurement Results

The ratio of each polymerization unit of the polymer precursor 2, expressed as the molar ratio, was as follows: VBA-derived polymerization unit:MA-C6F-derived polymerization unit:HEMA-derived polymerization unit=33:32:35.

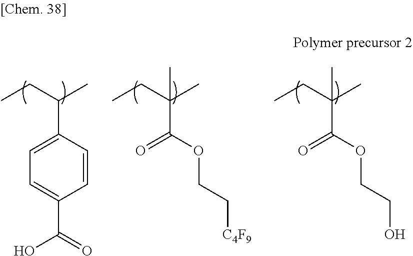

### GPC Measurement Results

### Mw=12,300, Mw/Mn=1.6

### Synthesis of Polymer Precursor 3

A 300 ml glass flask equipped with a stirrer was charged at room temperature (about 20° C.) with 4.3 parts by mass of BTFBE, 2.7 parts by mass of p-AcO-St, 21.4 parts by mass of MA-C4F, 6.6 parts by mass of glycidyl methacrylate (product of Tokyo Chemical Industry Co., Ltd., hereinafter referred to as Gly-MA), and 36.9 parts by mass of MEK. Then, 2.46 parts by mass of AIBN was added and the mixture was degassed with stirring. Subsequently, the flask was purged with nitrogen gas, the temperature inside the flask was raised to 79° C., and then a reaction was performed overnight. To the reaction system was dropped 250 parts by mass of n-heptane, whereby a white precipitate was obtained. This precipitate was filtered out and dried under reduced pressure at a temperature of 45° C. to give a polymer precursor 3 as a white solid with a yield of 83%.

### NMR Measurement Results

The ratio of each polymerization unit of the polymer precursor 1, expressed as the molar ratio, was as follows: BTFBE-derived polymerization unit:p-AcO-St-derived polymerization unit:MA-C4F-derived polymerization unit:Gly-MA-derived polymerization unit=15:11:43:31.

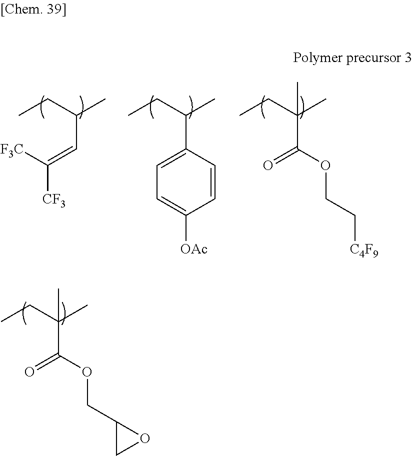

### GPC Measurement Results

### Mw =10,200, Mw/Mn =1.5

### Synthesis of Pentafunctional Acrylate-Containing Liquid-Repellent Agent 1

A 300 ml glass flask equipped with a stirrer was charged at room temperature with 12 parts by mass of hexamethylene diisocyanate (product of Tokyo Chemical Industry Co., Ltd., hereinafter referred to as HDI), 30 parts by mass of a mixture of dipentaerythritol pentaacrylate and dipentaerythritol hexaacrylate (product of Shin-Nakamura Chemical Co., Ltd., hydroxy value: 95), 0.06 parts by mass of dibutylhydroxytoluene (product of Tokyo Chemical Industry Co., Ltd., hereinafter referred to as BHT), 1.1 parts by mass of triethylamine (product of Tokyo Chemical Industry Co., Ltd.), and 60 parts by mass of propylene glycol monomethyl ether acetate (product of Tokyo Chemical Industry Co., Ltd., hereinafter referred to as PGMEA). The flask was purged with dry air, the temperature inside the flask was raised to 45° C., and then a reaction was performed overnight to give a pentafunctional monoisocyanate solution.

A 200 ml glass flask equipped with a stirrer was charged with 30 parts by mass of the pentafunctional monoisocyanate solution, 45 parts by mass of the polymer precursor 1, and 34 parts by mass of PGMEA. The flask was purged with dry air, the temperature inside the flask was raised to 45° C., and then a reaction was performed overnight. This solution was cooled to room temperature (about 20° C.) to give a pentafunctional acrylate-containing liquid-repellent agent 1.

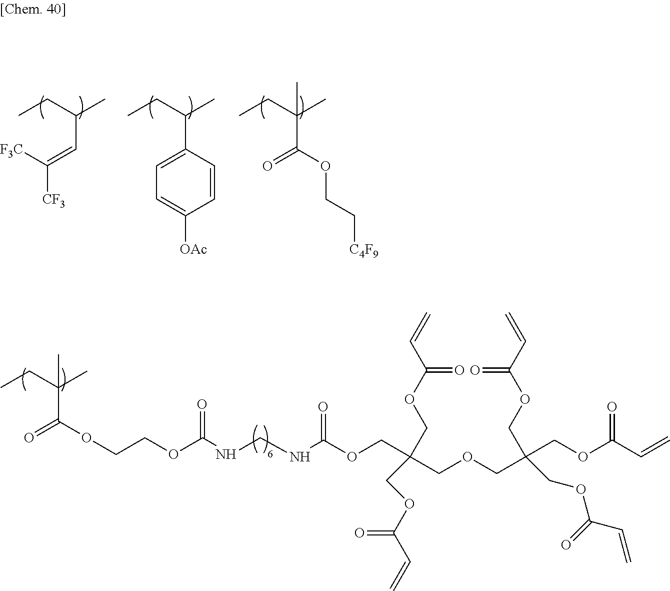

### Pentafunctional Acrylate-Containing Liquid-Repellent Agent 1

### GPC Measurement Results

### Mw=14,900, Mw/Mn=1.3

### Synthesis of Pentafunctional Acrylate-Containing Liquid-Repellent Agent 2)

A 300 ml glass flask equipped with a stirrer was charged at room temperature with 13 parts by mass of m-xylylene diisocyanate (product of Tokyo Chemical Industry Co., Ltd., hereinafter referred to as XDI), 30 parts by mass of a mixture of dipentaerythritol pentaacrylate and dipentaerythritol hexaacrylate (hydroxy value: 95), 0.06 parts by mass of BHT, 1 part by mass of triethylamine, and 60 parts by mass of PGMEA. The flask was purged with dry air, the temperature inside the flask was raised to 45° C., and then a reaction was performed overnight to give a pentafunctional monoisocyanate solution.

A 200 ml glass flask equipped with a stirrer was charged with 30 parts by mass of the pentafunctional monoisocyanate solution, 41 parts by mass of the polymer precursor 1, and 34 parts by mass of PGMEA. The flask was purged with dry air, the temperature inside the flask was raised to 45° C., and then a reaction was performed overnight. This solution was cooled to room temperature (about 20° C.) to give a pentafunctional acrylate-containing liquid-repellent agent 2.

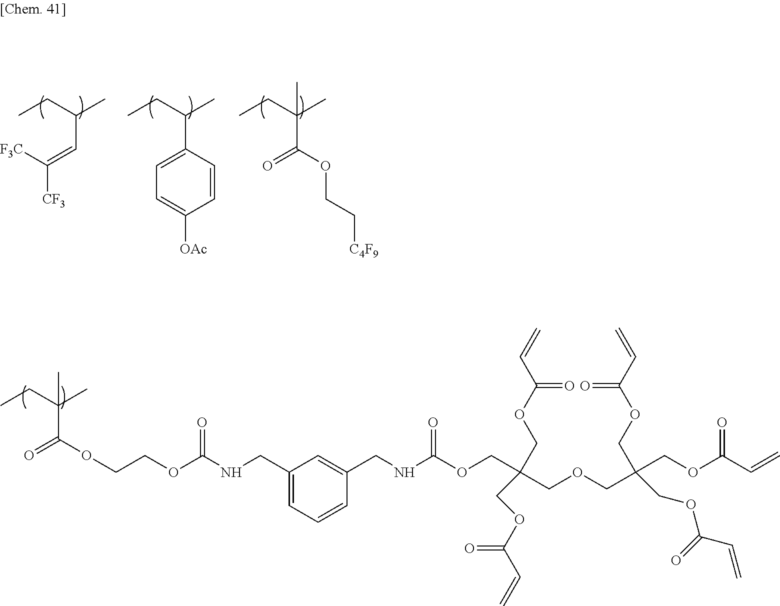

### Pentafunctional Acrylate-Containing Liquid-Repellent Agent 2

### GPC Measurement Results

### Mw=14,400, Mw/Mn=1.4

### Synthesis of Pentafunctional Acrylate-Containing Liquid-Repellent Agent 3

A 300 ml glass flask equipped with a stirrer was charged at room temperature with 14 parts by mass of 1,4-dicyclohexylmethane diisocyanate (product of Tokyo Chemical Industry Co., Ltd., hereinafter referred to as CHDI), 30 parts by mass of a mixture of dipentaerythritol pentaacrylate and dipentaerythritol hexaacrylate (hydroxy value: 95), 0.06 parts by mass of BHT, 1 part by mass of triethylamine, and 60 parts by mass of PGMEA. The flask was purged with dry air, the temperature inside the flask was raised to 45° C., and then a reaction was performed overnight to give a pentafunctional monoisocyanate solution.

A 200 ml glass flask equipped with a stirrer was charged with 30 parts by mass of the pentafunctional monoisocyanate solution, 41 parts by mass of the polymer precursor 1, and 34 parts by mass of PGMEA. The flask was purged with dry air, the temperature inside the flask was raised to 45° C., and then a reaction was performed overnight. This solution was cooled to room temperature (about 20° C.) to give a pentafunctional acrylate-containing liquid-repellent agent 3.

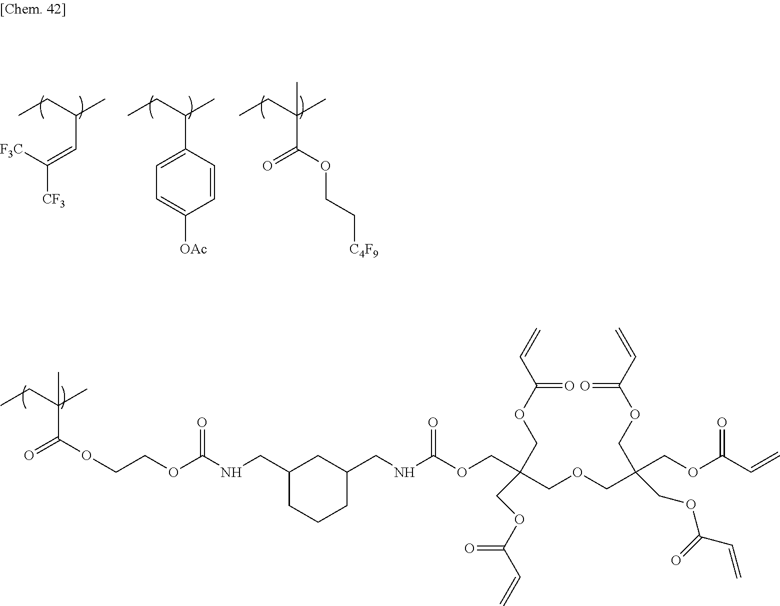

### Pentafunctional Acrylate-Containing Liquid-Repellent Agent 3

### GPC Measurement Results

### Mw=13,200, Mw/Mn=1.5

### Synthesis of Pentafunctional Acrylate-Containing Liquid-Repellent Agent 4

A 300 ml glass flask equipped with a stirrer was charged at room temperature with 12 parts by mass of HDI, 30 parts by mass of a mixture of dipentaerythritol pentaacrylate and dipentaerythritol hexaacrylate (hydroxy value: 95), 0.06 parts by mass of BHT, 1.1 parts by mass of triethylamine, and 60 parts by mass of PGMEA. The flask was purged with dry air, the temperature inside the flask was raised to 45° C., and then a reaction was performed overnight to give a pentafunctional monoisocyanate solution.

A 200 ml glass flask equipped with a stirrer was charged with 30 parts by mass of the pentafunctional monoisocyanate solution, 50 parts by mass of the polymer precursor 2, and 34 parts by mass of PGMEA. The flask was purged with dry air, the temperature inside the flask was raised to 45° C., and then a reaction was performed overnight. This solution was cooled to room temperature (about 20° C.) to give a pentafunctional acrylate-containing liquid-repellent agent 4.

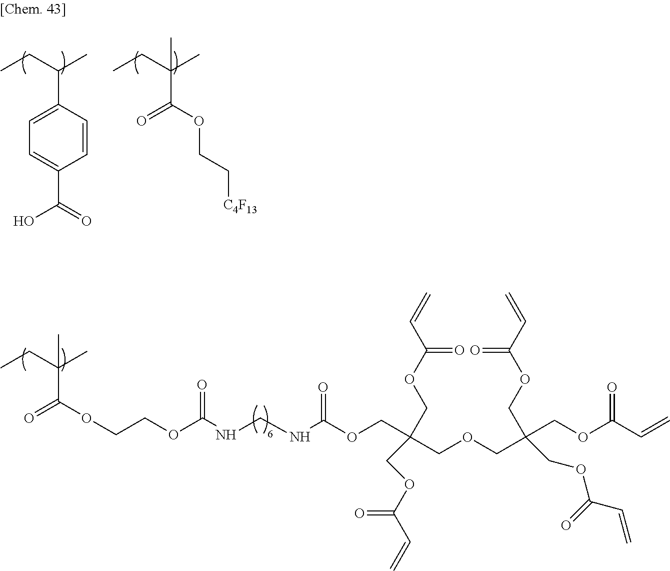

### Pentafunctional Acrylate-Containing Liquid-Repellent Agent 4

### GPC Measurement Results

### Mw=14,900, Mw/Mn=1.3

### Synthesis of Pentafunctional Acrylate-Containing Liquid-Repellent Agent 5

A 300 ml glass flask equipped with a stirrer was charged at room temperature with 5.1 parts by mass of succinic anhydride, 30 parts by mass of a mixture of dipentaerythritol pentaacrylate and dipentaerythritol hexaacrylate (hydroxy value: 95), 0.05 parts by mass of BHT, 1.1 parts by mass of triphenylphosphine, and 60 parts by mass of PGMEA. The flask was purged with dry air, the temperature inside the flask was raised to 45° C., and then a reaction was performed overnight to give a pentafunctional carboxylic acid solution.

A 200 ml glass flask equipped with a stirrer was charged with 30 parts by mass of the pentafunctional carboxylic acid solution, 67 parts by mass of the polymer precursor 3, and 40 parts by mass of PGMEA. The flask was purged with dry air, the temperature inside the flask was raised to 45° C., and then a reaction was performed overnight. This solution was cooled to room temperature (about 20° C.) to give a pentafunctional acrylate-containing liquid-repellent agent 5.

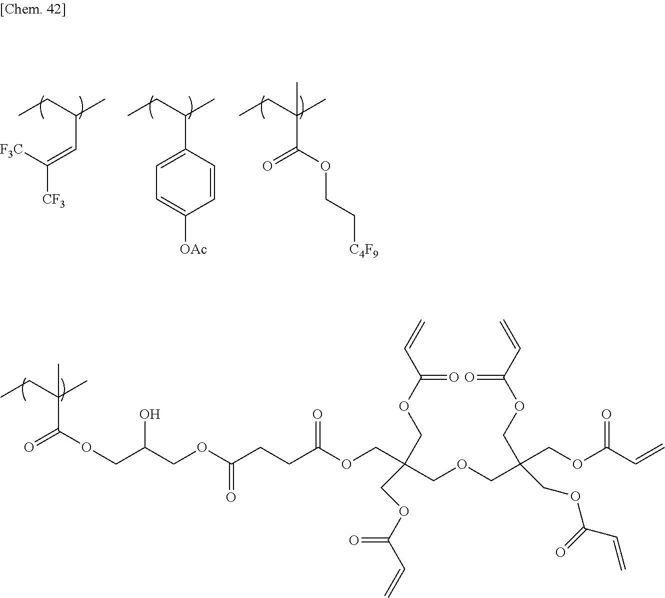

### Pentafunctional Acrylate-Containing Liquid-Repellent Agent 5

### GPC Measurement Results

### Mw=16,400, Mw/Mn=1.3

### Synthesis of Comparative Monofunctional Acrylate-Containing Liquid-Repellent Agent 1

A 100 ml glass flask equipped with a stirrer was charged with 10 parts by mass of the polymer precursor 2, 0.07 parts by mass of triethylamine, and 30 parts by mass of PGMEA. Then, 1.6 parts by mass of Karenz AOI (product of Showa Denko K.K.) was added and the mixture was reacted at 45° C. for four hours. After completion of the reaction, the reaction solution was concentrated, and then 100 g of n-heptane was added to precipitate a precipitate. The precipitate was filtered out and dried under reduced pressure at 40° C. to give 11.1 g of a comparative monofunctional acrylate-containing liquid-repellent agent 1 as a white solid with a yield of 75%.

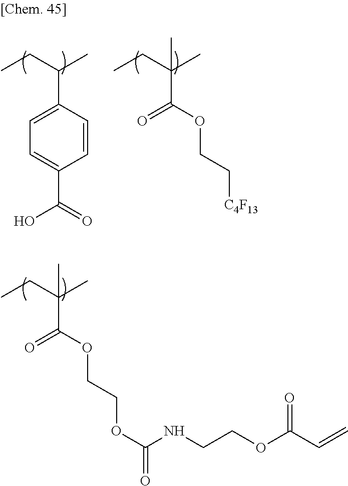

### Comparative Monofunctional Acrylate-Containing Liquid-Repellent Agent 1

### ¹³C-NMR Measurement Results

In the comparative monofunctional acrylate-containing liquid-repellent agent 1, the ratio of the amount of the Karenz AOI-derived acrylic acid derivative introduced (reacted ratio) to the amount of residual hydroxy groups (unreacted ratio), expressed as the molar ratio, was 96:4. It was also found that the ratio of each polymerization unit unreactive with the crosslinking group site (VBA-derived polymerization unit, MA-C6F-derived polymerization unit) remained unchanged from that of the polymer precursor 2 used (i.e., the same as before the introduction of the crosslinking group).

### 3. Preparation of Curable Composition

### Preparation of Curable Composition 1

An amount of 0.3 parts by mass of the produced pentafunctional acrylate-containing liquid-repellent agent 1, 1.0 parts by mass of Omnirad 369 (product of IGM Resins B.V.) as a polymerization initiator, 9.0 parts by mass of A9550 (product of Shin-Nakamura Chemical Co., Ltd.) as a crosslinking agent, 9.0 parts by mass of ZCR-1569H (Nippon Kayaku Co., Ltd.) as an alkali-soluble resin, and 56 parts by mass of PGMEA and 24 parts by mass of PGME as solvents were blended. The resulting solution was filtered through a 0.2 μm membrane filter to prepare a curable composition 1.

### Preparation of Curable Composition 2

A curable composition 2 was prepared as in Preparation of curable composition 1 except that the pentafunctional acrylate-containing liquid-repellent agent 2 was used instead of the pentafunctional acrylate-containing liquid-repellent agent 1.

### Preparation of Curable Composition 3

A curable composition 3 was prepared as in Preparation of curable composition 1 except that the pentafunctional acrylate-containing liquid-repellent agent 3 was used instead of the pentafunctional acrylate-containing liquid-repellent agent 1.

### Preparation of Curable Composition 4

A curable composition 4 was prepared as in Preparation of curable composition 1 except that the pentafunctional acrylate-containing liquid-repellent agent 4 was used instead of the pentafunctional acrylate-containing liquid-repellent agent 1.

### Preparation of Curable Composition 5

A curable composition 5 was prepared as in Preparation of curable composition 1 except that the pentafunctional acrylate-containing liquid-repellent agent 5 was used instead of the pentafunctional acrylate-containing liquid-repellent agent 1.

### Preparation of Comparative Curable Composition 1

An amount of 1.0 parts by mass of the produced comparative monofunctional acrylate-containing liquid-repellent agent 1, 1.0 parts by mass of Omnirad 369 (product of IGM Resins B.V.) as a polymerization initiator, 9.0 parts by mass of A9550 (product of Shin-Nakamura Chemical Co., Ltd.) as a crosslinking agent, 9.0 parts by mass of ZCR-1569H (Nippon Kayaku Co., Ltd.) as an alkali-soluble resin, and 56 parts by mass of PGMEA and 24 parts by mass of PGME as solvents were blended. The resulting solution was filtered through a 0.2 μm membrane filter to prepare a comparative curable composition 1.

### 4. Evaluation of Partition Walls

The curable compositions 1 to 5 and comparative curable composition 1 obtained in “3. Preparation of curable composition” were used to form partition walls. The partition wall properties were evaluated and compared. Table 1 shows the results.

### Formation of Partition Walls

A 10 cm square ITO substrate was washed with ultrapure water and then acetone. Subsequently, the substrate was subjected to UV-ozone treatment for five minutes using a UV-ozone treatment device (available from Sen Lights Corporation, model number: PL17-110). Then, the curable compositions 1 to 5 and comparative curable composition 1 obtained in “3. Preparation of curable composition” were each applied to the resulting UV-ozone-treated substrate using a spin coater at a rotation speed of 1,000 rpm, followed by heating on a hot plate at 100° C. for 150 seconds. Thus, fluorine-containing coating films and a comparative fluorine-containing coating film each having a thickness of 2 μm were formed. The resulting resin films were each exposed by irradiation with i-rays (wavelength: 365 nm) using a mask aligner (product of SUSS MicroTec) with a mask having a 5 μm line-and-space pattern.

The resulting exposed fluorine-containing coating films were subjected to evaluation of the developer solubility and the partition wall properties (sensitivity and resolution) and measurement of the contact angle.

### Developer Solubility

Each exposed resin film on the ITO substrate was immersed in an alkali developer at room temperature for 80 seconds to evaluate the solubility in the alkali developer. The alkali developer used was a 2.38 mass % tetramethylammonium hydroxide aqueous solution (hereinafter sometimes referred to as TMAH). The solubility of the partition walls was evaluated by measuring the film thickness of the partition walls after the immersion using a contact film thickness meter. The partition walls were deemed “soluble” if they were completely dissolved, and “insoluble” if the resist film remained undissolved.

### Partition Wall Properties (Sensitivity and Resolution)

The optimal exposure Eop (mJ/cm²) for forming partition walls in the aforementioned line-and-space pattern was determined and used as an index of sensitivity.

Moreover, the resulting pattern of partition walls was observed under a microscope to evaluate the resolution. The pattern was rated as “excellent” with no visible line-edge roughness, “good” with slightly visible line-edge roughness, and “poor” with significant line-edge roughness.

### Contact Angle

Each substrate with partition walls obtained by the above process was heated at 230° C. for 60 minutes, and the entire substrate surface was subjected to UV-ozone treatment or oxygen plasma treatment for 10 minutes. The contact angle of the surface of the partition walls or comparative partition walls with propylene glycol monomethyl ether acetate (PGMEA) was measured before and after the UV-ozone treatment or oxygen plasma treatment using a contact angle meter (GMs-601 available from Kyowa Interface Science Co., Ltd.).

The UV-ozone treatment device used was the same as described earlier. Moreover, the oxygen plasma treatment was performed using an oxygen plasma treatment device Plasma Dry Cleaner PDC210 available from Yamato Scientific Co., Ltd. at an oxygen gas flow rate of 30 cc/min and an output of 300 W.

### UV Ozone Resistance, Oxygen Plasma Resistance

The retention of the PGMEA contact angle before and after the UV-ozone treatment or oxygen plasma treatment was calculated using the following equation based on the contact angles before and after the UV-ozone treatment or oxygen plasma treatment obtained in the contact angle measurement. The retention was used as an index of UV ozone resistance or oxygen plasma treatment resistance.

UV ozone resistance=PGMEA contact angle after UV-ozone treatment/PGMEA contact angle before UV-ozone treatment×100

Oxygen plasma resistance=PGMEA contact angle after oxygen plasma treatment/PGMEA contact angle before oxygen plasma treatment×100

TABLE 1

| | | Partition wall | | | | | |
|---|---|---|---|---|---|---|---|
| | | 1 | 2 | 3 | 4 | 5 | Comparative 1 |
| | | Curable composition | | | | | |
| | | 1 | 2 | 3 | 4 | 5 | Comparative 1 |
| Number of ethylenically unsaturated double bonds | | 6 | 6 | 6 | 5 | 6 | 1 |
| Developer solubility | Unexposed portion | Soluble | Soluble | Soluble | Soluble | Soluble | Soluble |
| | Exposed portion | Insoluble | Insoluble | Insoluble | Insoluble | Insoluble | Insoluble |
| Partition wall properties | Sensitivity (mJ/cm²) | 56 | 56 | 56 | 56 | 56 | 100 |
| | Resolution | Excellent | Excellent | Excellent | Excellent | Excellent | Excellent |
| PGMEA contact angle | Before UV-ozone treatment | 43 | 45 | 43 | 39 | 42 | 40 |
| | After UV-ozone treatment | 42 | 43 | 41 | 37 | 41 | 15 |
| UV ozone resistance | Contact angle retention | 98% | 96% | 95% | 95% | 98% | 38% |
| PGMEA contact angle | Before oxygen plasma treatment | 44 | 45 | 43 | 38 | 43 | 41 |
| | After oxygen plasma treatment | 43 | 44 | 42 | 37 | 41 | 14 |
| Oxygen plasma resistance | Contact angle retention | 98% | 98% | 98% | 97% | 95% | 34% |

As seen in Table 1, the evaluation of the developer solubility shows that each partition wall correspond to a negative resist in which only the unexposed portions are soluble. The evaluation of the partition wall properties shows that each partition wall exhibited comparable sensitivity and had “Excellent” resolution as the 5 μm line-and-space pattern of the mask was transferred with good resolution without visible line-edge roughness. In other words, it was found from these evaluations that the liquid-repellent agents of the present disclosure and the comparative liquid-repellent agent had only a small impact on the formed partition walls.

The partition walls formed from the curable compositions 1 to 5 showed a low rate of decrease in the PGMEA contact angle of the exposed portions (corresponding to the partition wall upper surfaces) due to the UV-ozone treatment or oxygen plasma treatment, and retained the contact angle before the UV-ozone treatment or oxygen plasma treatment.

In contrast, the partition walls formed from the comparative curable composition 1 showed a great decrease in the PGMEA contact angle due to the UV-ozone treatment or oxygen plasma treatment. The partition walls formed from the curable compositions 1 to 5 had a significantly higher liquid repellency after the UV-ozone treatment or oxygen plasma treatment.

1. A liquid-repellent agent (A), comprising a polymer containing: a polymerization unit (a1) derived from a hydrocarbon having an alkyl group in which at least one hydrogen atom is replaced with a fluorine atom and which may contain an ether-oxygen atom; and one or two or more types of polymerization units (a2) other than the polymerization unit (a1),
wherein the number of ethylenically unsaturated double bonds in the polymerization units (a1) and (a2) is 3 or greater.

2. A liquid-repellent agent (A), comprising a polymer containing: a polymerization unit (a1) derived from a hydrocarbon having an alkyl group in which at least one hydrogen atom is replaced with a fluorine atom and which may contain an ether-oxygen atom; and a polymerization unit (a21′) containing two or more ethylenically unsaturated double bonds.

3. The liquid-repellent agent (A) according to claim 1,
wherein the polymer has a fluorine atom content of 10 to 55 mass %.

4. The liquid-repellent agent (A) according to claim 1,
wherein the ethylenically unsaturated double bonds are each derived from an acrylic group or a methacrylic group.

5. The liquid-repellent agent (A) according to claim 1,
wherein the polymer has a structure represented by the following formula (1): 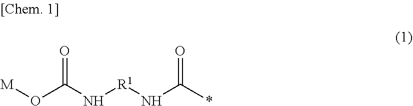
wherein M represents a structure containing two or more ethylenically unsaturated double bonds;
R¹ represents a divalent organic linking group with or without a substituent; and * represents a bond.

6. The liquid-repellent agent (A) according to claim 1,
wherein the polymer has a structure represented by the following formula (2): 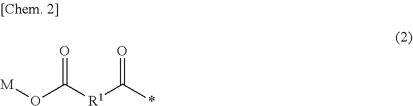
wherein M represents a structure containing two or more ethylenically unsaturated double bonds;
R¹ represents a divalent organic linking group with or without a substituent; and * represents a bond.

7. The liquid-repellent agent (A) according to claim 1,
wherein the polymer has a structure represented by the following formula (3): 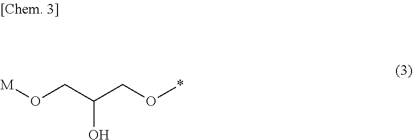
wherein M represents a structure containing two or more ethylenically unsaturated double bonds;
and * represents a bond.

8. A curable composition, comprising:
the liquid-repellent agent (A) according to claim 1;
a resin component (B) including at least one of an alkali-soluble resin (B1) or an alkali-soluble monomer (B2); and
a photopolymerization initiator (C).

9. The curable composition according to claim 8, further comprising a crosslinking agent (D).

10. The curable composition according to claim 8, further comprising a polymerization inhibitor (E).

11. The curable composition according to claim 8, further comprising an ultraviolet absorber (F).

12. The curable composition according to claim 8, further comprising a chain transfer agent (G).

13. The curable composition according to claim 8, which is for forming a partition wall.

14. A cured product, obtained by curing the curable composition according to claim 8.

15. A partition wall, comprising the cured product according to claim 14.

16. An organic electroluminescent element, comprising the partition wall according to claim 15.

17. A method of producing a fluorine-containing coating film, comprising:
mixing the liquid-repellent agent (A) according to claim 1, a resin component (B) including at least one of an alkali-soluble resin (B1) or an alkali-soluble monomer (B2), and a photopolymerization initiator (C) to prepare a curable composition;
applying the curable composition to a substrate, and
after the applying, curing the curable composition by irradiation with high energy rays.

18. A fluorine-containing coating film, formed on a substrate,
wherein a value of a contact angle of the fluorine-containing coating film with propylene glycol monomethyl ether acetate after oxygen plasma treatment for 30 minutes is 95% to 100% of a value of a contact angle of the fluorine-containing coating film with propylene glycol monomethyl ether acetate before the oxygen plasma treatment.

19. A fluorine-containing coating film, formed on a substrate,
wherein a value of a contact angle of the fluorine-containing coating film with propylene glycol monomethyl ether acetate after UV-ozone treatment for 30 minutes is 95% to 100% of a value of a contact angle of the fluorine-containing coating film with propylene glycol monomethyl ether acetate before the UV-ozone treatment.
